(19) United States
(12) Patent Application Publication
(10) Pub. No.: US 2014/0179049 A1
(43) Pub. Date: Jun. 26, 2014

(54) SILICON/GERMANIUM-BASED NANOPARTICLE PASTES WITH ULTRA LOW METAL CONTAMINATION

(71) Applicant: NanoGram Corporation, Milpitas, CA (US)

(72) Inventors: Ha Thi-Hoang Nguyen, Milpitas, CA (US); Masaya Soeda, San Jose, CA (US); Weidong Li, San Jose, CA (US); Uma Srinivasan, Mountain View, CA (US)

(21) Appl. No.: 14/087,872

(22) Filed: Nov. 22, 2013

Related U.S. Application Data
(60) Provisional application No. 61/740,277, filed on Dec. 20, 2012.

(51) Int. Cl. C09D 11/14; C08B 11/02; C08B 11/20; H01L 31/18

(52) U.S. Cl. CPC C09D 11/14; H01L 31/18; C08B 11/02; C08B 11/20
USPC 438/57; 106/31.13; 536/100

(57) ABSTRACT

Silicon based nanoparticle inks are described with very low metal contamination levels. In particular, metal contamination levels can be established in the parts-per-billion range. The inks of particular interest generally comprise a polymer to influence the ink rheology. Techniques are described that are suitable for purifying polymers soluble in polar solvents, such as alcohols, with respect metal contamination. Very low levels of metal contamination for cellulose polymers are described.

### CROSS REFERENCE TO RELATED APPLICATIONS

This application claims priority to copending U.S. provisional patent application 61/740,277 filed Dec. 20, 2012, entitled “Silicon/Germanium-Based Nanoparticle Pastes With Ultra Low Metal Contamination,” incorporated herein by reference.

### FIELD OF THE INVENTION

The invention relates to silicon/germanium-based nanoparticle pastes incorporating polymers with appropriate functional groups and an ultra low metal contamination in the parts per billion range. The invention further relates to forming semiconductor structure using the pure pastes. The invention further relates to ultra pure polymers, especially cellulose polymers, suitable for paste formation and to methods for purifying the cellulose polymers.

### BACKGROUND OF THE INVENTION

Silicon-based materials are important commercial materials. In particular, elemental silicon is a widely used semiconductor material for electronic and solar cell applications. The semiconducting properties and electron mobilities of silicon can be altered using dopants. The formation of semiconductor devices generally involves the formation of regions of the device with selectively doped silicon in which the dopants alter the electrical conduction properties or other desired properties. Through the selected doping process different domains of the device can be formed that provide functionalities for particular device to exploit the semiconductor properties, such as a diode junction formed with separate materials with a p-type dopant and an n-type dopant. For example, n-type dopants provide excess electrons that can populate the conduction bands, and the resulting materials are referred to as n-type semiconductors. P-type dopants provide electron deficiencies or holes and are used to form p-type semiconductors. Through appropriate doping, a wide range of devices can be formed, such as transistors, diodes and the like. Silicon oxides, silicon nitrides and silicon oxynitrides can be used as dielectric materials, and these materials can be particularly desirable for use along with silicon semiconductors for their compatibility and lack of metals that can migrate to a silicon semiconductor.

In general, processing costs are a significant consideration for commercial applications. It can be desirable to use printing approaches for moderate resolution applications since commercial printing equipment is available and processing costs can be reasonable. Screen printing is a widely used printing technique commercially. Screen printing is generally performed with a paste with a range of acceptable rheological properties consistent with the screen printer. Other commercially compatible deposition approached include, for example, inkjet printing, spin coating, spray coating, knife edge coating and the like.

The wide ranges of semiconductor applications generate commercial relevance for silicon materials in many forms. For example, the formation of large area thin film transistors or the like generates a demand for alternative semiconductor processing approaches. Also, with increasing energy costs and increasing demand for energy, the market for solar cells has been correspondingly increasing. A majority of commercial solar cells comprise photoconducting silicon semiconductors, and differential doping of the semiconductor facilitates harvesting of the photocurrent. Some solar cells have patterning of silicon doping for the formation of doped contacts along the horizontal plane of the device. Thin film silicon solar cells can have dopant variation in a vertical orientation relative to the plane of the device. With increasing performance demands, there are pressures to keep costs down so that improvements in material processing is very desirable as an approach to address performance issues while keeping costs at acceptable levels. Germanium is a semiconducting material that can be an alternative to silicon with similar semiconducting properties. Also, silicon and germanium can form semiconducting alloys with each other.

### SUMMARY OF THE INVENTION

In a first aspect, the invention pertains to a nanoparticle ink comprising at least about 0.1 weight percent silicon/germanium-based inorganic nanoparticles and at least about 1 weight percent polymer having a molecular weight of at least 500 daltons. In general, the paste has an iron content of no more than about 100 ppb, and the polymer comprises an organic polymer comprising a cellulose-based polymer, a poly(vinyl alcohol), a poly(vinyl ester), polyvinyl amides, a polysiloxane polymer, polyacrylates, polyacrylic acid, polyvinyl butyrl or a combination thereof.

In further aspects, the invention pertains to a cellulose polymer having a iron contamination, chromium contamination, copper contamination and nickel contamination individually of no more than about 100 ppb by weight as evaluated in a 7 weight percent solution

In additional aspects, the invention pertains to a method for the purification of an organic polymer soluble at a concentration of at least about 0.5 weight percent in ethanol and having a molecular weight of at least 200 amu, the method comprising separating the polymer from an acidified aqueous solution having a pH of no more than about 4 pH units to obtain a polymer with a reduced metal content.

Moreover, the invention pertains to a method for the purification of a cellulose polymer, the method comprising filtering a dissolved solution of the polymer through an ion removal media to reduce the iron contamination to no more than about 100 ppb as determined in a 7 weight percent polymer solution.

### BRIEF DESCRIPTION OF THE DRAWINGS

FIG. 1 is a bottom perspective view of a back contact photovoltaic cell.

FIG. 2 is a bottom view of the back contact photovoltaic cell depicted in FIG. 1 showing only the semiconducting layer with doped islands deposited thereon.

FIG. 3 is a graph showing plots of the sheer rate dependent viscosity of different paste samples prepared with either purified or non-purified ethyl cellulose.

FIG. 4a is an optical microscopy image of a line with a width of 200 μm, screen printed during the 10^{th} print cycle with a screen printing paste comprising 3-6 wt % silicon nanoparticles and 0.85 wt % ethyl cellulose. The hash marks in the lower right corner of the image correspond to a length scale of 50 μm.

FIG. 4b is an optical microscopy image of a dot with a diameter of 200 μm, screen printed during the 10^{th} print cycle with a screen printing paste comprising 3-6 wt % silicon nanoparticles and 0.85 wt % ethyl cellulose. The hash marks in the lower right corner of the image correspond to a length scale of 50 μm.

FIG. 5 is an analogous optical microscopy image of a line, manually screen printed after the 10^{th} print cycle with a screen printing paste not comprising ethyl cellulose. The screen printing paste was not subject to centrifugal planetary mixing after post-centrifugation sonication. The hash marks in the lower right corner of the image correspond to a length scale of 50 μm.

FIG. 6a is an optical microscopy image of a line with a width of 100 μm, screen printed during the 10^{th} print cycle with the screen printing paste used to print the line and dot depicted in FIGS. 4a and 4b. The hash marks in the lower right corner of the image correspond to a length scale of 50 μm.

FIG. 6b is an optical microscopy image of a dot with a diameter of 100 μm, screen printed during the 10^{th} print cycle with the screen printing paste used to print the line and dot depicted in FIGS. 4a and 4b. The hash marks in the lower right corner of the image correspond to a length scale of 50 μm.

FIG. 7a is an optical microscopy image of a line with a width of 200 μm, screen printed on a polished wafer during the 10^{th} print cycle with the screen printing paste used to print the line and dot depicted in FIGS. 4a and 4b. The hash marks in the lower right corner of the image correspond to a length scale of 50 μm.

FIG. 7b is an optical microscopy image of a dot with a diameter of 200 μm, screen printed on a polished wafer during the 10^{th} print cycle with the screen printing paste used to print the line and dot depicted in FIGS. 4a and 4b. The hash marks in the lower right corner of the image correspond to a length scale of 50 μm.

FIG. 8 is an optical microscopy image of a screen used to print a 200 μm line with the screen printing paste used to print the dot and line depicted in FIGS. 4a and 4b. The image was taken after 2 hours of continuous printing.

FIG. 9 is an optical microscopy image of a screen used to print a 100 μm dot with the screen printing paste used to print the dot and line depicted in FIGS. 6a and 6b. The image was taken after the 2 hours of continuous printing.

FIG. 10 is an optical microscopy image of a screen analogous to a screen used to print a 200 μm dot using a screen printing ink not comprising ethyl cellulose after 2 hours of continuous printing. The hash marks in the lower right corner of the image correspond to a length scale of 50 μm.

FIG. 11 is a graph containing plots of viscosity versus shear rate for 3 different ink pastes formed from 20 nm, n++, doped silicon nanoparticles with (top 2 plots) and without (bottom plot) EC as a polymer additive.

FIG. 12a is an optical microscopy image displaying top-view of silicon wafer substrate with screen printed line. The line was printed with a screen printing ink comprising 3-6 wt % silicon nanoparticles and 0.85 wt % EC and the hash marks in the lower right corner of the image correspond to a length scale of 50 μm.

FIG. 12b is an optical microscopy image displaying top-view of silicon wafer substrate with screen printed dot. The dot was printed with a screen printing ink comprising 3-6 wt % silicon nanoparticles and 0.85 wt % EC and the hash marks in the lower right corner of the image correspond to a length scale of 50 μm.

FIG. 12c is an optical microscopy image displaying top-view of silicon wafer substrate with screen printed pattern. The pattern was printed with a screen printing ink comprising 3-6 wt % silicon nanoparticles and 0.85 wt % EC and the hash marks in the lower right corner of the image correspond to a length scale of 50 μm.

FIG. 13a is an optical microscopy image displaying top-view of silicon wafer substrate with screen printed line. The line was printed with a screen printing ink comprising 3-6 wt % silicon nanoparticles and 2.5 wt % EC and the hash marks in the lower right corner of the image correspond to a length scale of 100 μm.

FIG. 13b is an optical microscopy image displaying top-view of silicon wafer substrate with screen printed dot. The dot was printed with a screen printing ink comprising 3-6 wt % silicon nanoparticles and 2.5 wt % EC and the hash marks in the lower right corner of the image correspond to a length scale of 100 μm.

FIG. 13c is an optical microscopy image displaying top-view of silicon wafer substrate with screen printed pattern. The pattern was printed with a screen printing ink comprising 3-6 wt % silicon nanoparticles and 2.5 wt % EC and the hash marks in the lower right corner of the image correspond to a length scale of 100 μm.

FIG. 14a is an optical microscopy image displaying top-view of silicon wafer substrate with screen printed line. The line was printed with a screen printing ink comprising 0.65 wt % EC and the hash marks in the lower right corner of the image correspond to a length scale of 50 μm.

FIG. 14b is an optical microscopy image displaying top-view of silicon wafer substrate with screen printed dot. The dot was printed with a screen printing ink comprising 0.65 wt % EC and the hash marks in the lower right corner of the image correspond to a length scale of 50 μm.

FIG. 14c is an optical microscopy image displaying top-view of silicon wafer substrate with screen printed pattern. The pattern was printed with a screen printing ink comprising 0.65 wt % EC and the hash marks in the lower right corner of the image correspond to a length scale of 50 μm.

FIG. 15a is an optical microscopy image displaying top-view of silicon wafer substrate with screen printed line. The line was printed with a screen printing ink comprising 3.3 wt % EC and the hash marks in the lower right corner of the image correspond to a length scale of 100 μm.

FIG. 15b is an optical microscopy image displaying top-view of silicon wafer substrate with screen printed dot. The dot was printed with a screen printing ink comprising 3.3 wt % EC and the hash marks in the lower right corner of the image correspond to a length scale of 100 μm.

FIG. 15c is an optical microscopy image displaying top-view of silicon wafer substrate with screen printed pattern. The pattern was printed with a screen printing ink comprising 3.3 wt % EC and the hash marks in the lower right corner of the image correspond to a length scale of 100 μm.

### DETAILED DESCRIPTION OF THE INVENTION

Highly pure nanoparticle pastes or other inks can comprise silicon/germanium-based nanoparticles with a metal contamination in a parts-per-billion (ppb) range. The ink can comprise a polymer comprising suitable functional groups in the polymer repeat unit to provide for desirable rheology properties for the inks at relatively high nanoparticle concentration. To achieve the desired purity level of the inks, the polymers can be purified prior to incorporation into the ink composition, e.g. a paste. Processes are described herein that can be used to purify polymers soluble in polar solvents, and in particular have been successful in greatly lowering metal contamination in cellulose based polymers. The nanoparticles can comprise elemental silicon/germanium, silicon/germanium oxides, silicon/germanium nitrides, silicon/germanium oxynitrides or mixtures hereof. In some embodiments, the nanoparticles can be doped to a desired level. The pastes can be formulated for depositing using commercially practical techniques, such as screen printing. Due to the ultra low metal contaminant levels, the inks are well suited for processing to form semiconductor devices. Generally, the nanoparticles are selected to deliver desired compositions for processing of the devices, and the nanoparticles may or may not be incorporated into an ultimate device. In particular, the devices can be suitable for forming solar cell structures or for the formation of components for printed electronics.

The nanoparticle inks of particular interest generally comprises silicon/germanium-based nanoparticles, a solvent, which can comprise a blend of solvent compounds, and one or more polymers, which can be selected in an amount to adjust the paste properties. The metal contamination of the various components as well as the processing of the inks are each important to achieve the objectives of the ink with an extremely low metal contamination level. The polymers generally have functional groups in the polymer repeat unit that determine their solubility in polar solvents as well as for compatibility with the nanoparticles. Generally, the nanoparticles are selected based on desired properties of the nanoparticles. In general, the inks comprise one or more solvents with properties selected based on compatibility with the other ink components, rheology properties of the ink, printing properties, compatibility with printer components, and post printing processing conditions and target properties. For example, in some paste formulations, a lower boiling solvent is combined with a higher boiling solvent so that the lower boiling solvent can evaporate at least partially in the printing process or thereafter to stabilize the printed paste and to limit spreading of the printed paste.

The nanoparticles generally have an average diameter of no more than about 100 nm and smaller average particle sizes can be desirable as described further below. In some embodiments, the nanoparticles can be highly uniform with respect to size and/or composition, although blends of nanoparticles can be desirable for some embodiments. Also, the nanoparticles can be highly dispersible in an appropriate solvent such that the nanoparticles can have a desirable secondary particle size in the dispersion. Properly formed nanoparticle dispersions can be incorporated into a paste or other nanoparticle inks to obtain desirable paste uniformity and printability.

Silicon/germanium refers herein, including the claims, to elemental silicon, elemental germanium, alloys thereof or mixtures thereof. Similarly, the use of silica or germania nanoparticles are described in some embodiments, and silica/germania refers herein, including the claims, to silica (silicon oxide), germania (germanium oxide), combinations thereof and mixtures thereof. The discussion of silica herein generally can correspondingly apply to germania based on the similarities of the compositions. In addition, silicon/germanium nitrides and silicon/germanium oxynitrides correspondingly refer to silicon nitrides, silicon oxynitrides, germanium nitrides, germanium oxynitrides, combinations thereof and mixtures thereof. While the discussion below focuses on silicon based nanoparticles, the analogous processing of and compositions with germanium and alloys of silicon and germanium follows from the discussion based on the similar chemistries of the elements. To simplify the discussion, elemental germanium, germanium compounds and alloys of germanium with silicon are generally not explicitly discussed, and references to silicon based compounds generally apply similarly to germanium based compounds.

The silicon based nanoparticles can be synthesized by any appropriate technique. For example, silicon oxide nanoparticles can be synthesized by sol-gel processes, flame pyrolysis, and thermal pyrolysis. Also, elemental silicon nanoparticles can be synthesized by plasma techniques such as described in U.S. Pat. No. 7,718,707 to Kelman et al., entitled “Method for Preparing Nanoparticle Thin Films,” incorporated herein by reference.

Laser pyrolysis is a desirable approach for the synthesis of silicon based nanoparticles with a desired composition and extremely low metal contamination. In particular, laser pyrolysis can be useful for the synthesis of silicon based nanoparticles with desired stoichiometry as well as a desired doping including high doping levels. Laser pyrolysis uses an intense light beam to drive a reaction that can be designed to form highly uniform silicon based nanoparticles with desirable characteristics. The particles are synthesized in a flow that initiates at a reactant nozzle and ends at a collection system. Dopant levels can be adjusted using dopant precursors within the reactant stream. Particle sizes can be adjusted by correspondingly adjusting the synthesis conditions during laser pyrolysis. For the formation of high quality inks, it is generally desirable to synthesize nanoparticles having an average primary particle size of no more than about 100 nm. Laser pyrolysis can be used to form very uniform primary particle sizes, optionally with a desired dopant level. The uniform nanoparticles can be well dispersed in the inks at relatively high concentrations, and the properties of the inks can be controlled to be suitable for a selected deposition process.

In the laser pyrolysis process, to obtain incorporation of the dopant element into the product particles, the dopant elements can be delivered into the reactant stream as a suitable precursor composition along with the silicon precursor. In general, the reactant stream can comprise vapor precursors and/or aerosol precursors, although for silicon materials highly pure gaseous precursors can be desirable to achieve high purity of the product particles. Laser pyrolysis can be used to form doped silicon particles with a wide range of selected dopants or combinations of dopants. Specifically, dopant levels of several atomic percent can be achieved. The ability to achieve high dopant levels make the corresponding inks particularly desirable for applications where dopants are transferred to a semiconducting material or for the formation of devices with these high dopant levels. The high dopant levels can be achieved while also having control of average particle sizes, low impurity levels and while achieving dispersible particle with good uniformity. For the doping of semiconductor substrates, desirable dopants include, for example, B, P, Al, Ga, As, Sb and combinations thereof. The general use of laser pyrolysis for the formation of a range of materials is described in published U.S. Pat. No. 7,384,680 to Bi et al., entitled “Nanoparticle Production and Corresponding Structures,” incorporated herein by reference.

The synthesis of uniform dispersible silicon nanoparticles is described further in published U.S. patent application 2008/0160265 to Hieslmair et al., entitled “Silicon/Germanium Particle Inks, Doped Particles, Printing and Processes for Semiconductor Applications,” incorporated herein by reference. Laser pyrolysis was used to synthesize doped silicon nanoparticles used to form improved inks that are described in the Examples below. Also, the synthesis of highly dispersible, uniform silicon oxide nanoparticles by laser pyrolysis with an optional dopant is described in U.S. Pat. No. 7,892,872 to Hieslmair et al., entitled “Silicon/Germanium Oxide Particle Inks, Inkjet Printing, and Processes for Doping Semiconductor Substrates,” incorporated herein by reference. The synthesis of silicon nitride (Si₃N₄) nanoparticles by laser pyrolysis is described in published U.S. patent application 2011/0135928 to Ravilisetty et al., entitled “Metal Silicon Nitride or Metal Silicon Oxynitride Submicron Phosphor Particles and Methods for Synthesizing These Phosphors,” incorporated herein by reference. Silicon oxynitride nanoparticles can be synthesized using laser pyrolysis through the controlled introduction of a blend of ammonia (NH₃) and an oxygen source, such as N₂O or CO₂, as a secondary reactant with silane (SiH₄) or other silicon source based on the teachings in these references. Alternatively, silicon oxynitride particles can be formed by the partial reduction of silicon oxide nanoparticles with NH₃ or the oxidation of silicon nitride nanoparticles with an oxidizing agent, such as O₂ or O₃.

Laser pyrolysis can also be adapted for the synthesis of silicon based nanoparticles with very low metal contamination. In particular for transition metal impurities, silicon-based nanoparticles with a low impurity levels can be particularly desirable for semiconductor related application of the nanoparticles. In some embodiments, it is desirable for iron and other transition metal contaminants to be in the relatively low parts-per-billion levels in inks comprising the silicon-based nanoparticles, as described further below. For silicon based nanoparticles, highly pure gas phase silicon reactants can be introduced, and gas/vapor phase secondary reactants, such as ammonia and oxygen can similarly be introduced. For many desirable dopants, suitable pure dopant sources are also available. Also, laser pyrolysis apparatuses and processes have been redesigned to achieve exceedingly low metal contaminations for silicon based nanoparticles. Also, the product particles are collected and handled in a controlled manner to reduce or eliminate metal contaminants resulting from collection and handling the particles. Based on these improved designs, silicon based nanoparticles can be synthesized with a very low contaminant levels with respect to metal elements. For example, the particles can be collected in an environment isolated from the ambient air. The synthesis of doped silicon nanoparticles with very low contamination levels is described in published U.S. patent application 2011/0318905A to Chiruvolu et al., entitled “Silicon/Germanium Nanoparticle Inks, Laser Pyrolysis Reactors for the Synthesis of Nanoparticles and Associated Methods,” incorporated herein by reference. For example, laser pyrolysis apparatus designs provide for the synthesis of highly uniform silicon nanoparticles at commercially significant rates, which can have a very low level of total metal contaminants. The particles can have a metal contamination concentration of any individual metal of no more than about 300 ppb and a total metal contaminant level of no more than about 1 parts per million by weight (ppm). As described further below, the processing of the nanoparticles into an ink can involves processing to further reduce the metal contamination contributions from the nanoparticles.

The dispersions of the silicon based nanoparticles can be formed at high concentrations, and the properties of the dispersions can be engineered over desirable ranges based on particular applications. The characteristics of the dispersion can be evaluated through an examination of secondary particle properties, such as Z-average particle size and particle size distribution, measured in the dispersion using generally light scattering, which are measures of the size of the dispersed particles in the liquid. In particular, good dispersions can be characterized with respect to the secondary particle sizes and distributions. Dispersions that are too concentrated for direct measurement of secondary particle sizes can be diluted, for example, to a 0.1 weight percent concentration for the secondary particle characterization, based on an assumption that secondary particle size is not particularly concentration dependent in stable dispersions. In particular, it can be desirable for the Z-average particle size to be no more than about 250 nm and in further embodiments no more than about 150 nm. As described further below, it has been found that rheology properties can provide further information on the ink properties that do not seem to be reflected in the secondary particle size measurements, and this understanding provides an important tool in ink, e.g., paste, design and characterization.

Also, silicon oxide nanoparticles can be stably dispersed at relatively high concentrations. The silicon oxide nanoparticles can be optionally surface modified with a suitable composition to facilitate dispersion. The dispersion of silicon oxide nanoparticles is described further in U.S. Pat. No. 7,892,872 to Hieslmair et al., entitled “Silicon/Germanium Particle Inks, Inkjet Printing and Processes for Doping Semiconductor Substrates,” incorporated herein by reference. The dispersion of silicon oxide, silicon nitride and silicon oxynitride particles for the production of the highly pure pastes are found below. The dispersion of silicon nitride nanoparticles is described in published PCT patent application WO 01/32799A to Reitz et al., entitled “Particle Dispersions,” incorporated herein by reference.

An initial good dispersion can be formed with the silicon based nanoparticles in an appropriate solvent to form the good dispersion, and the solvent or solvent blend can be manipulated to form an overall ink, i.e., a dispersion formulated for a particular deposition process, with selected properties while maintaining the good dispersion or stable ink with the nanoparticles. Specifically, techniques have been developed for more versatile exchange of solvents or formation of solvent blends such that a desirable solvent system can be selected for a particular printing approach. Particle concentrations can be correspondingly adjusted to desired values. With the ability to provide highly uniform silicon based nanoparticles in high concentration dispersions with selected solvents, inks can be formulated that can be printed using desirable approaches.

To further remove contaminants in the formation of the silicon based nanoparticle dispersions, centrifugation can be used to remove contaminants from the dispersions with the silicon based nanoparticles remaining disbursed in the liquid. Thus, for example, in nanoparticle dispersions with relatively high particle concentrations most metal concentrations can be reduced to levels of no more than about 20 parts per billion by weight (ppb) for inks with about 10 weight percent particle concentration, and total metal contamination can be reduced to levels of no more than about 100 ppb by weight dispersion. The dispersions can be used to form desired inks, which as noted above generally further comprise a polymer.

The engineering of a desired silicon ink can involve several parameters. A starting point for ink formulations can involve the formation of well dispersed silicon-based nanoparticles. Once the particles are well dispersed, the resulting dispersion can be appropriately modified to form a selected ink. Solvent can be removed by evaporation to increase the particle concentration, and/or solvent or solvents can be added to form a solvent blend or a lower concentration of the particles in the dispersion. A good dispersion is characterized by the nanoparticles remaining suspended, with no significant particle settling, for at least an hour without application of additional mixing, although generally dispersions of interest are stable for extended period of time. At higher particle concentrations of the inks, the secondary particle sizes cannot be directly measured by optical methods. But the higher concentration inks can be evaluated in part by the lack of particle settling, i.e., remaining a good dispersion, and by diluting the concentrated ink to a concentration where the secondary particle size can be measured.

It has been found that appropriate characterization of dispersions generally involves several properties to provide sufficient information to evaluate the significant functional characteristics of the inks. In particular, measurements of dispersed secondary particle sizes do not correlate fully with the printing properties once the quality of the ink has achieved a relatively good level. But rheology measurements can provide further information relating to the handling of the inks in a deposition context. As is conventional in the art, references to viscosity without explicit indication of a shear rate imply that the viscosity measurements are at a low shear limit, which can be effectively expressed as a shear of 2 s⁻¹. Also unless indicated otherwise, viscosity measurements are made at room temperature, e.g., 20-25° C. Thus, appropriate rheology measurements can be effectively used to provide further significant characteristics of the inks along with primary particles size measurements, secondary particle size measurements, and compositions of the inks.

The design of a silicon based nanoparticle ink can balance several objectives. The selected deposition technique can provide boundaries on the parameters of the ink properties. For many silicon ink formulations, the inks have a relatively large nanoparticle concentration, for example, at least about 0.5 weight percent or possibly significantly higher. Also, the quality of the resulting silicon nanoparticle deposit, such as the uniformity, smoothness and the like, can also be dependent on the subtle aspects of the ink characteristics. The rheology of the ink can be tested to help to estimate the quality of the ink with respect to resulting deposition. With improved processing techniques and ink formulations described herein, the inks can be formulated with high silicon based particle concentrations and with desirable rheological properties.

Suitable inks are described for coating deposition or printing, which generally involves a patterning during deposition. Suitable printing inks can be formulated for inkjet printing, gravure printing and screen printing. Suitable coating techniques include, for example, spin coatings, spray coating, knife edge coating and the like. Other inks can be similarly formulated based on this teaching. To obtain desired thickness of deposited inks, a coating or printing process can be repeated to form multiple layers of the ink with a corresponding greater thickness.

The discussion herein focuses on the formation of inks with some polymer added to adjust the ink properties. In particular, highly pure pastes, such as screen printing pastes, can be formed with very low metal contamination, in which the pastes have at least moderate amounts of polymers to influence the rheology. In particular, screen printing pastes are generally non-newtonian fluids. However, the techniques herein to provide extremely low metal contaminations can be adapted for other types of inks that may have lesser amounts of polymers suitable for the corresponding particular printing of coating process.

The properties of an ink can be designed around the composition of the solvent, the polymer, the nanoparticles, any additional composition and their concentrations. In other words, while certain features of an ink may be set by the particular application, any remaining parameters can be adjusted to achieve a target ink property. Generally, the desired ink properties are selected to meet desired processing and functional targets. For example, the rheology depends on the concentrations and compositions of the various components of the ink, and the rheology can be targeted within certain parameter ranges to be compatible with a desired deposition approach, such as spin coating, inkjet printing or screen printing. Furthermore, the compositions generally are selected to exhibit desired processing following deposition. In particular, the particle properties, such as composition and average primary particle size, are generally significant for the further processing to form a desired structure.

The polymer compositions and concentrations are generally selected in particular to alter the deposition properties of the ink. Specifically, the polymers can be used to increase the ink viscosity without necessarily correspondingly increasing the particle concentration and to introduce non-Newtonian behavior to the ink. The post deposition properties of the inks are generally also very significant. For example, the polymer compositions can be selected to be eliminated upon heating or to convert to a desirable form, such as polysiloxanes forming a silicon oxide composition with appropriate heating.

As used herein, polymers are used to refer to moderate to high molecular weight polymers and to exclude technical polymers with a low molecular weight, such as butane, i.e., di-ethylene. In general, polymers of interest are relatively high molecular weight to introduce desired rheological properties to the inks, and a reasonable lower limit of 200 atomic mass units (amu) for an average molecular weight can be used to distinguish low molecular weight oligomers and smaller polymers that may not strongly influence the rheology of a solution. While some polymers may not provide for accurate molecular weight determinations, such as cellulose polymers, it is clear generally for these polymers that their average molecular weight is significantly greater than 200 amu.

In some embodiments, it has been found that alcohol solvents can be used effectively for formulating desirable inks. In particular, coating inks can be formed with individual solvents, such as appropriate alcohols. For example, it has been found that high quality spin coating inks can be formulated with a single solvent component. However, for many embodiments of printing inks with silicon nanoparticles, a desired ink can advantageously comprises a blend of solvents with desired properties to achieve target ink properties. In general, if a blend of solvents is used, the solvents form a single liquid phase either due to miscibility or solubility of the solvents relative to each other. Screen printing pastes can be formulated with a higher boiling solvent and a lower boiling solvent to effectively control printing properties and stability with low spreading. Specifically, the blend of solvents generally can comprise a first low boiling temperature solvent, generally having a boiling point of no more than about 165° C. and a second high boiling temperature solvent, generally having a boiling point of at least about 170° C. For example, the lower boiling solvent can be removed at least partially upon printing of the ink to stabilize the printed material, and the higher boiling solvent can be removed upon further processing of the printed material.

To form nanoparticle pastes for deposition using certain approaches, such as screen printing, the pastes are generally desired to be non-newtonian fluids that have a decreased viscosity at high shear rates. To achieve desired rheological properties, the pastes generally comprise a reasonable amount of suitable polymer. In some embodiments, polymers have functional groups in the polymer repeat unit, such as hydroxyl groups, ether groups, ester groups or combinations thereof, that contribute to solubility of the polymers in alcohol based solvents, although in some embodiments other solvents can be used. Suitable copolymers can be copolymers or the like. Polymers of particular interest include, for example, celluloses, polyvinyl alcohols, polyvinyl esters, polyvinyl amides, polysiloxanes, polyacrylates, polyvinyl butyrl and mixtures thereof. Mixtures of ethyl cellulose and another polymer, such as a polyacrylate or polyvinyl butyrl, have been found to provide desirable ink properties, although individual polymers have been found to provide good ink properties also, and other polymer combinations can be expected to also provide desirable ink properties. A particular selection of polymers can be based on a particular target ink properties.

Suitable polymers have been known to improve silicon paste properties. For example, the use of polyvinyl alcohol and ethyl cellulose as binders for screen printing silicon particle pastes is described in U.S. Pat. No. 4,947,219 to Boehn, entitled “Particulate Semiconductor Devices and Methods,” incorporated herein by reference. Also, the use of high molecular weight molecules, such as ethyl cellulose, have been described for use in silicon nanoparticle inks in published U.S. patent application 2011/0012066 to Kim et al., entitled “Group IV Nanoparticle Fluid,” incorporated herein by reference. As described herein, cellulose ethers, such as ethyl cellulose, have been found to significantly improve screen printing properties for high quality silicon nanoparticle pastes. In particular, the presence of the cellulose significantly improves the rheology properties of the silicon nanoparticle pastes with appropriately engineered solvent system. Thus, ethyl cellulose or combinations of polymers comprising ethyl cellulose are of significant interest.

The achievement of the low contaminant levels for silicon based pastes and other polymer containing inks described herein involves the simultaneous combination of several significant considerations. A necessary condition for the formation of nanoparticle pastes with the extremely low contamination levels described herein is that the components to form the pastes have correspondingly low metal contamination levels. Specifically, to obtain an ink with the desired low metal contamination it is important to include silicon-based nanoparticles with extremely low metal contamination, polymers with extremely low metal contamination and solvents with extremely low metal contamination. The synthesis and collection of nanoparticles with low metal contamination has been achieved, and semiconductor grade solvents can be used to form silicon-based inks with extremely low metal contamination as described herein. Correspondingly, the handling of the materials has been designed to also not introduce metal contamination beyond acceptable amounts. The important achievement described herein is obtaining suitable polymers to achieve desired rheological properties while maintaining the low metal contamination levels. Based on the teachings herein such ink production can be performed at reasonable costs such that the resulting inks are suitable for commercial use for moderate cost applications.

Desirable polymers for the formation of screen printing pastes, e.g., ethyl cellulose, can provide a desired non-Newtonian behavior with a decrease in viscosity at high shear as well as clean printing through the screen with a low level of clogging or image blurring. To achieve desired purities of ethyl cellulose, purification techniques have been developed that provide for the formation of cellulose polymers with extremely low metal contamination with filtration and/or acid washing. While purer forms of other polymers are commercially available, the purification techniques developed for ethyl cellulose can be adapted to the purification of other polymers with highly functional groups introducing solubility of the polymers in alcohol based solvents to achieve even greater purity levels for these polymers. In particular, polyvinyl alcohols, polyvinyl esters, such as polyvinyl acetate, polyvinyl amides, such as poly vinylacrylamide, polyacrylates, polyacrylic acid, polyvinyl butyrl or a combination thereof can be suitable organic polymers to make the silicon-based inks. Also, polysiloxanes can be desirable polymers for silicon-based inks, and commercial polysiloxanes are available commercially at reasonable purities. A mixture of polymers can be desirable to achieve certain objectives related to processing related to deposition of the inks or conversion of the inks into a desired product. In some embodiments, it can be desirable to use a blend of polysiloxane polymers and an organic polymer as described below. In addition to the polymer composition, to achieve desired fluid properties of the inks, other parameters of potential significance can be the average polymer molecular weight or the viscosity of the dissolved polymer without the nanoparticles. Selection of suitable polymer or polymer mixtures that meet high purity pastes generally include: solubility in solvents which are suitable for dispersion of nanoparticles as discussed earlier, ability to form stable inks/pastes with nanoparticles, ability to eliminate clogging of screens during printing, besides other printed-feature characteristics and high purity requirements discussed above.

In general, the removal of metal contaminants at the parts per billion level has been found to be difficult to accomplish. Cellulose based polymers in particular are derivatives of natural fibers, which therefore cannot be synthesized in a pure form, but cellulose polymers are highly desirable for forming silicon based inks. Two approaches for purification have been found to provide significant removal of metal contaminants from desirable polymers, especially ethyl cellulose. Specifically, filters suitable for metal removal from liquids have been found to be surprisingly effective to reduce metal contamination from polymers in solution. The filtrations can be repeated to reduce metal contamination to very low levels. Furthermore, an acid wash process has been surprisingly found to be particularly effective to remove metals especially iron, from polymers that are soluble in alcohol based solvents. The combination of filtration and an acid wash have been found to be extremely effective at removing metal contamination. The ability to remove metal contaminants from the polymers down to very low levels provides significant ability to use the silicon based inks for semiconductor applications where higher amounts of metal contamination would significantly compromise performance of the resulting semiconductor products, such as photovoltaic devices or integrated circuits.

With the incorporation of a significant amount of polymer into a silicon based nanoparticle ink, polymer contamination becomes a significant issue. The polymers are selected for their compatibility with the dispersion of silicon-based nanoparticles and for the rheological properties of the polymers in a dispersion. In particular, the polymers can be selected to be soluble in the liquid used for the nanoparticle dispersion, and the dissolved polymers should not destabilize the nanoparticle dispersion. The amount of polymer can be selected to achieve desired ink properties, and generally the inks comprise at least about 0.5 weight percent polymer. In general, the polymers provide ability to increase the viscosity of the ink independent of particle concentration, which can be beneficial for certain ink deposition processes. For the formation of screen-printing pastes, the polymer and polymer concentration generally are selected to provide for non-newtonian rheology.

The polymer contamination levels in a 7 weight percent solution can be reduced to levels of iron contamination of no more than about 300 parts-per-billion by weight (ppb). With respect to total transition metal contamination in the polymer, the polymer in a 7 weight percent solution can have a contamination of transition metals of no more than about 1000 ppb. For silicon based nanoparticle inks, contaminant levels for iron, copper, chromium and nickel contamination can be individually at levels of no more than about 100 ppb, and in some embodiments significantly lower. Iron, chromium, copper and nickel contaminants are particularly undesirable silicon semiconductor contaminants. With respect to transition metals generally, the silicon based nanoparticle inks can have total transition metal contamination of no more than about 400 ppb, and in some embodiments significantly lower.

With respect to polymer processing to increase polymer purity, the polymers are generally dissolved in a suitable solvent. For the various purification processes, an initial purification can be performed by centrifuging the dissolved polymer to settle out impurities while leaving the soluble polymer in the supernatant. For filtration, the polymer solution is passed over a metal removal filter either with gravity flow or under a suitable pressurized system. Suitable filters include, for example, an ion exchange type filter, electrostatic or similar metal ion binding filter, and commercial filters for purifying liquids for semiconductor processing are available. The polymer solution can be passed sequentially through a plurality of filters to achieve additional metal ion removal.

To perform the acid wash of the polymer for metal removal, an appropriate acid is mixed with the polymer solution to acidify the polymer. The acidified polymer is mixed for an appropriate period of time to equilibrate the acidified solution. After sufficient mixing, the acidified polymer solution can be subject to separation, e.g. driven by centrifugation, to settle the polymer from solution. After centrifugation, the liquid can be decanted off from the settled polymer. The acid wash and centrifugation steps can be repeated to remove acid and neutralize the polymer solution. The liquid removed from the centrifuged material can be tested to facilitate a decision on whether or not to perform an additional acid wash. For example, the pH and/or metal content of the supernatant liquid can be tested. The acid wash processing and filtration can be performed sequentially with a selected order to further remove metal ion contaminants.

Following purification, the polymer can be dried, concentrated, diluted, neutralized with respect to pH, transferred to another solvent system or otherwise appropriately processed. In some embodiments, the polymer can be processed to store and or transport the polymer, which can be performed in a dried form or in solution. The polymer can be used ultimately for the formation of a silicon based nanoparticle ink or for the use in another application in which the purified polymer does not introduce undesirable metal ion contaminants. Alternatively, the polymer can be brought up in a solution selected for further processing for use to form a desired product, such as the formation of a silicon based nanoparticle ink.

Silicon nanoparticle inks can be deposited using a selected method. In particular, the purified polymers have been found to be particularly desirable for the formation of silicon based nanoparticle paste that have excellent screen printing properties. After printing, the inks can be used to form components of semiconductor devices or as a dopant source to be driven into an underlying semiconductor material. In particular, silicon inks can be used for forming components of solar cells or of electronic devices, such as thin film transistors. In some embodiments, the particles can be incorporated directly into a component of an ultimate product.

### Polymer Purification

Techniques have been developed for the introduction of polymers with low metal contamination to control the fluid properties of the inks as well as purification of polymers that are desirable for the formation of silicon based inks. Suitable polymers are generally soluble in liquids that are compatible with dispersing the silicon based nanoparticles while providing desirable rheological properties of the resulting inks. The polymers are generally purified using the techniques described herein to obtain a polymer with suitable purity that a corresponding ink with a desired purity level can be formed. Some polymers of interest may be available with metal contaminant levels within or near acceptable levels, and these polymers may be further purified using the purification techniques to further reduce the metal contaminant levels. The purification techniques are specifically designed for the removal of metal contaminants, which presumably are associated with the polymers as metal ions. In particular, the purification process can comprise filtration and/or acid washing of the polymers. Through the purification techniques, extremely low levels of metal contaminants can be achieved generally in the parts-per-billion (ppb) by weight range. In particular, using the purification techniques cellulose polymers can be purified to achieved these very low metal contaminant levels. Following purification, the purified polymers can be stored for later use in appropriate containers to avoid introduction of contaminants or directly used for the production of silicon based inks with low metal contaminant levels or directly for other uses. Depending on the immediate destination of the polymer, suitable processing can be used to further process the purified polymer solutions, such as drying or suitably altering the polymer solution.

To obtain a desired fluid property, the silicon based nanoparticle inks with a polymer generally can comprise, for example, a cellulose-based polymer, a polyvinyl ester, a polyvinyl alcohol, a polysiloxane polymer, combinations thereof, or the like. Generally, the polymers for purification as described herein have a solubility of at least about 0.5 weight percent in ethanol. Cellulose is a naturally occurring polysaccharide that is found in plants, especially in wood and a variety of natural fibers. The polymer repeat unit in cellulose is D-glucose linked through the 1, 4 carbons with a beta linkage. Cellulose polymer generally refers to a regenerated form of the natural polymer that is formed by dissolving the natural polymer. The dissolving process is believed to reduce the polymer molecular weight through partial degradation of the polymer that results in a reduced crystallinity. Cellulose derivatives can provide desirable ink properties. Cellulose derivatives include, for example, cellulose esters, such as cellulose nitrate and cellulose acetate, and cellulose ethers, such as methyl cellulose, ethyl cellulose, hydroethyl cellulose, hydroxypropyl cellulose, carboxymethyl cellulose, aminoethyl cellulose, and benzyl cellulose. In particular, ethyl cellulose has desirable properties and is used in the examples below.

Some additional polymers of interest for the pastes are now summarized. As with the cellulose polymers, the polymers generally have at least some solubility in alcohol solvents and are not soluble in water. As a particular reference point, the polymer can have a solubility of at least about 0.5 weight percent in ethanol, although generally the polymers have a higher solubility in many alcohols. Polyvinyl esters have a polymer repeat unit —CH₂CH(OCOR)—.

Polyvinyl acetate (—CH₂CH(OCOCH₂CH₃)—) is a commercially important polymer that can be used for forming silicon based nanoparticle inks. Other notable polyvinyl esters include, for example, polyvinyl propionate and polyvinyl butyrate. Polyvinyl alcohol has a repeat unit of —CH₂CHOH—. Polyvinylacetamide has a repeat unit of —CH₂CH(NCOR)—. Polyacrylates have a repeat unit of —CH₂CR₁(COOR₂)—. Polyvinylalcohol has a repeat unit of —CH₂CH(COH)—. Polyvinylbutyral has a repeat structure with —C₈H₁₄O₂— with a 6 member ring having two oxygen atoms spaced apart by a carbon atom and three carbon atoms along the polymer backbone. In general, the various R groups are organic groups, which usually are small alkyl groups such as methyl, ethyl or properly groups, although in principle the groups could have large numbers of carbon atoms. R₁ can be H or an organic group. The molecular weight of various polymers can be selected to adjust the properties of the resulting ink.

Polysiloxane polymers have a polymer repeat unit of —SiR₁R₂—O—, where R₁ and R₂ are organic groups, such as a methyl group, an ethyl group, a phenyl group derivatives thereof or combinations thereof. The characteristic of a particular polysiloxane generally depends on the length of the polymer backbone, the nature of the organic side chains and the presence and degree of any crosslinking. For the formation of pastes, a polysiloxane can be used in the paste that is crosslinked to some degree to provide desirable rheology. For the formation of other inks, it can be desirable to incorporate uncrosslinked polysiloxane oils into the ink to provide for Newtonian behavior of the ink. Moderately pure polysiloxanes are described in U.S. Pat. No. 5,179,185 to Yamamoto et al., entitled “High Purity Hydroxy-Terminated Phenyl Ladder Polysiloxane and Method for Producing Same,” incorporated herein by reference. The use generally of polysiloxanes in nanoparticle dispersions is described in U.S. Pat. No. 8,314,176 to Du et al., entitled “Composites of Polysiloxane Polymers and Inorganic Nanoparticles,” incorporated herein by reference. Relatively pure polysiloxanes are available commercially. The purification techniques described herein can be used to further purify these polymers.

The polymer purification procedure can comprise filtration of the polymer and/or acid washing of the polymer with centrifugation. Electronics grade filters can be used to provide suitable metal removal while avoiding the introduction of other metal contaminants by the filter. For example, filters are commercially available that are designed for metal removal from solutions used in electronics applications. The filters can be obtained that are suitable for use with alcohol solvents. As described in more detail below, a solution comprising dissolved polymer is passed through one or more filters under appropriate conditions to provide for the removal of metal contaminants from the polymer through effective ion exchange type interactions.

An acid wash has been found to be surprisingly effective for the purification of polymers in polar organic solvents. In general, a solution of the dissolved polymer is mixed with an acidified solvent at a pH of no more than about 5 pH units. After mixing the solution well, the acidified solution is subjected to a separation process to separate the polymer from the solution, such as through a sedimentation process or phase separation process driven through centrifugation. The supernatant solution can be decanted from the precipitated polymer. The supernatant can be tested for its composition. The acid wash and separation can be repeated until the tested supernatant is consistent with a desirably purified polymer. The acid wash approach has been found to be extremely effective at removal of metal contaminants, especially for iron contaminants that have been found to be difficult to remove. A combination of the filtration purification and the acid wash purification can be used to purify a sample of polymer with a selected order of sequential use and optionally with the use of multiple purification steps of each type, such as a plurality of acid wash steps and/or a plurality of filtration steps. For example, a plurality of filtration steps can be effectively performed after acid wash steps.

In some embodiments, as shown in the Examples, appropriate filtration has been found to significantly reduce metal contamination of ethyl cellulose, and similar results are expected for other polymers with similar functional groups, such as ether groups, hydroxyl groups, ester groups, carboxylic acid groups, and combinations thereof. Initially, a polymer solution can be formed with one or more solvents to dissolve the polymer, and the resulting polymer solution can be appropriately filtered to reduce the metal associated with the polymer. A filtration method can comprise one or more filtration step, with each filtration step comprising passing the polymer solution through a selected filter. In particular, multiple filtration steps have been found to be very effective at reducing metal contamination. Also, the combination of filtration and an acid wash step also can result in very low metal contamination levels.

To form the polymer solution for a selected polymer to be filtered, the polymer can be dissolved in a suitable solvent or solvent blend. Generally, the solubility properties of the polymer direct the selection of the solvent for purification, and the solvent used for purification may or may not be the same solvent used for the ultimate use of the polymer, such as a silicon-based ink. If it is desired to dry the polymer following purification, small molecule solvents having relatively low boiling points can be desirable because they can be evaporated after filtration relatively more easily.

During each filtration step, the polymer solution can be gravity fed through the filter or filters or can be pressure fed through the filter or filters using modest pressure. Appropriate pressures can be determined with respect to the desired filtration rate, suitable pressures within the system and/or the desired level metal contaminant concentration in the polymer solution after filtration. In general, suitable filters from electronics applications have been found to be adaptable to the polymer purification process. Specifically, high performance ion exchange filters, ion removal media based on ion exchange groups, or trace metal removing filters based on electrokinetic ion binding processes have been found to be useful. Suitable filtration apparatuses using pressure fed filtration are commercially available, such as from 3M Purification, Inc., Zeta Plus EC (trace metal removal) and 40Q CUNO filters (ion removal media), or can be assembled readily from available fittings, tubing and other components.

In some embodiments, a filtration step can comprise sequential passage of a polymer solution through multiple filters. The filters can be arranged in a configuration such that the polymer solution to be filtered passes through each filter sequentially in a continuous filtration flow, or filter polymer solution can be collected and separately passed through another filter or the same filter. Each filter can be selected to have the same or different characteristics, such as compositions and structure, as other filters sequentially used.

Suitable filters can be designed for metal removal, such as through ion exchange or other binding of the metal ions. For example, Zeta Plus™ EC purifier cartridges from 3M Purification, Inc. are used in the electronics industry for trace metal removal, and these have been found to be suitable filters for polymer purification for metal removal. Other electronics or semiconductor grade ion exchange or similar metal removal filters, such as 40Q CUNO filters, generally can be similarly used or sequentially used. While the composition and structural configuration of the filters may not be particularly significant, filters can be selected to be compatible with the solvents used in the polymer solution. In some embodiments, the filters can be obtained that are suitable for use with alcohol solvents and/or acetone.

In some embodiments, the filters and any additional flow components that contact the polymer solution can be cleaned prior to use, such as with rinsing with an appropriate clean solvent. The clean solvent used for cleaning the filter and other additional components may or may not be the same solvent used to form the polymer solution. Generally, solvents commercial sold as “clean room grade” or “electronics grade” can be desirable with respect to purity and low metal contamination, although solvents can also be selected based directly on contaminant specification. Appropriate solvents include, for example, small molecules solvents having a low boiling point such as methanol, ethanol, propanol and acetone, which can be removed to concentrate solutions or to dry the polymer with a lower expenditure of time and/or energy.

As the polymer solution is passed over the filter, the polymer concentration in the eluting liquid may or may not stay constant due to retarded passage of polymer through the filter. Additional solvent can be passed over the filter to facilitate more complete removal of the polymer from the filter, although, in some embodiments, desirable filtration can be achieved without passing additional solvent over the filter. Further processing of the polymer can account for any dilution of the polymer solution based on the use of additional solvent to wash the polymer solution from the filter.

In general, to perform the filtration, the polymer solution has a concentration from about 0.01 weight percent polymer to about 15 weight percent, in further embodiments from about 0.025 to about 12 weight percent and in other embodiments from about 0.05 to about 10 weight percent. The use of a more concentrated polymer solution can result in a reduced amount of solvent use, but the viscosity can increase with concentration. A viscous polymer solution can have an undesirably low flow rate through the filter. Also, the polymer concentration can be influenced by the polymer solubility on a selected solvent system. The flow rate generally is influenced by the filter size, pressure, solution viscosity, configuration of the filtration system and the like. As noted in the Examples, acceptable flow rates can be achieved for actual systems.

In general, filtration can be effective to significantly reduce metal contamination in the polymers. Specifically, the iron, chromium, copper and nickel contamination of a polymer solution with 7 weight percent polymer can be individually reduced to levels of no more than about 250 parts per billion by weight (ppb), in further embodiments no more than about 150 ppb, in additional embodiments no more than about 100 ppb and in some embodiments no more than about 50 ppb. The polymers in a 7 weight percent solution can have a total metal contamination of no more than about 1000 ppb, in further embodiments no more than about 800 ppb and in additional embodiments no more than about 700 ppb. A person of ordinary skill in the art will recognize that additional ranges of metal contamination levels within the explicit ranges above are contemplated and are within the present disclosure.

In some embodiments, the polymer can be purified using acid washing methods additionally or alternatively to filtration methods. The acid washing methods described herein have been found to be surprisingly effective in reducing transition metal contamination in polymers of interest. An acid washing method can comprise contacting the polymer with an acid in solution and subsequently separating the polymer from the liquid phase in which the metals are concentrated in the liquid to remove metals from the polymer. Optionally, an acid washing method can comprise a pre-treatment process to remove at least some contaminants that are contained within the polymer, such as centrifuging the solubilized polymer to remove insoluble contaminants from the polymer solution. Also, an acid washing method can comprise a post-treatment wash or the like to remove acid or salt remaining in the polymer after separating the polymer.

In some embodiments, an acidified polymer solution can be formed by combining an acid, polymer and solvent, for example, by adding acid or an acidic solution to a polymer solution. To provide for convenient separation of the polymer from the solution comprising the metal contaminants, the solvent of the acidified polymer solution may not effectively dissolve the polymer. Thus, in some embodiments, the acid can be formed into a solution with a desired concentration or pH prior to addition to the polymer solution. The polymer solution can be formed by dissolving the polymer in a compatible solvent or solvent blend that dissolves the polymer. Suitable solvents or solvent blends depend on the polymer. In some embodiments, appropriate solvents for many polymers of interest can include, for example, alcohols or blends with alcohols. The acid solution can be an aqueous solution, and the combined mixture can be effectively used to isolate the polymer from the acidified solution if the polymer is insoluble or less soluble in an aqueous solution. Generally, it can be desirable to thoroughly mix the acidified polymer solution to help homogenize the solution and facilitate removal of metal ions from the polymer.

In some embodiments, the polymer solution can be optionally subjected to a pre-treatment process in which at least some impurities in the polymer are removed prior to the acid wash. The pre-treatment process can comprise centrifuging the polymer solution and separating/decanting the liquid phase containing the polymer from precipitated contaminants. Additionally or alternatively, filtration can be used for pretreatment of the polymer prior to performing an acid wash. A plurality of the same or different pretreatment steps can be used as desired.

The optionally pre-treated polymer solution can then be acidified if not initially formed in an acidic solution. In some embodiments, the polymer solution is formed separately from an acidic solution and the polymer solution is combined with an acid solution to contact the polymer and acid. The acid solution can comprise one or more acids in an appropriate solvent. In some embodiments, solvents can desirably facilitate separation of the polymer from the remaining solution components after the polymer solution and acid solutions are combined. In some embodiments, appropriate solvents can include, for example, blends of alcohol and water. Ethyl cellulose and polyvinyl acetate can be dissolved in a solvent comprising, for example, acetone, methanol, ethanol, other alcohols or blends thereof, and mixed with an aqueous acidic solution to perform the acid wash, and the combined solution is conducive to separation of the polymer with centrifugation or other separation technique, such as filtration with a filter compatible with the acid wash solvent.

In general, the acid composition and concentration of the acid are selected to be compatible with the polymer so that the polymer is not significantly decomposed or otherwise deleteriously affected by the acid. In some embodiments, the acid can comprise hydrochloric acid, sulfuric acid, phosphoric acid, carboxylic acids, such as acetic acid, combinations thereof or other acid or combination of acids that does not react with or decompose the polymer. In some embodiments, the concentration of polymer in the acidified solution can be between 0.01 weight percent (“wt %”) and 15 wt %, in other embodiments from about 0.025 wt % to about 12 wt % and in further embodiments, from about 0.05 wt % to about 10 wt %. The amount of acid can be adjusted to provide an appropriate pH to the acidified solution. In general, the pH can be less than about 5 pH units, in further embodiments from about 1.5 to about 4.5 pH units and in other embodiments from about 2 to about 4.25 pH units. In general, the solvent and acid composition is selected to be substantially free of metal contaminants so as to guard against the introduction of these contaminants into the polymer during acid washing. A person of ordinary skill in the art will recognize that additional ranges of concentration and pH within the explicit ranges above are contemplated and are within the present disclosure.

After forming the acidified polymer solution, the solution can be mixed well to facilitate release of metal ions into the solution. In some embodiments, the acidified polymer solution can be mixed with any reasonable device based on the volumes to be mixed, such as a stirrer, mechanical mixer, for example, a centrifugal planetary mixer, sonicator and/or other suitable mixing device. In some embodiments, the mixing can comprise mixing for at least about 10 minutes, in some embodiments no more than about 10 hours, in further embodiments from about 12 minutes to about 8 hours and in additional embodiments from about 15 minutes to about 6 hours. A person of ordinary skill in the art will recognize that additional ranges of mixing time within the explicit ranges above are contemplated and are within the present disclosure.

After the polymer and acid solutions are combined and optionally mixed for a desired amount of time, the solution comprising the transition metal contaminants solubilized away from the polymer can be removed by separating the polymer from the remaining solution components. In embodiments, the solution can be centrifuged to separate the polymer by sedimentation. If the polymer is soluble in the acidic solution, a solvent, generally miscible with the acidic solution, can be added to decrease the polymer solubility. For example, acetone or deionized water or other solvent can be added. The centrifuge can be operated generally to separate the polymer in a reasonable period of time and with good separation. In some embodiments, the centrifuge can be operated at least about 2500 rpm, in further embodiments at least about 3000 rpm and in additional embodiment at least about 4000 rpm. In additional or alternative embodiments, filtration can be used to separate the polymer from the acid wash solution. A person of ordinary skill in the art will recognize that additional ranges of centrifugation parameters within the explicit ranges above are contemplated and are within the present disclosure. The liquid phase comprising the transitional metal contaminants from the polymer can be separated, such as by decanting, from the solid phase comprising the polymer. The acid wash and polymer separation can be repeated to further decrease the metal contamination from the polymer. In general, the acid wash can be performed once, twice, three times, four times or more than four times.

In some embodiments, an acid wash procedure can comprise a wash step post-acid treatment to remove solvent and associated acid and salts, including metal contaminants, that remain after the separation of the polymers. In particular, after separation polymer from the solution components, the polymer can be mixed with an appropriate solvent to dilute any acid and/or salt remaining loosely associated with the polymer after centrifugation and separation of the liquid. In some embodiments, an appropriate solvent can comprise a solvent that does not appreciably dissolve the polymer but appreciably dissolves the acid used in the acid solution as well as salt byproducts produced by acid treating the polymer. The solvent can be added to the acid treated polymer and centrifuged to separate the polymer from the solvent. The solid phase comprising the polymer can then be separated from the liquid phase comprising the further removed acid and/or salts. After centrifugation of the wash mixture, the pH of the solution separated from the polymer can be checked. The wash steps of adding the wash solvent to the polymer and separating the liquid phase can be repeated until pH reaches a threshold value. In some embodiments, the acid wash can be repeated if the separated solution has a pH below, i.e., more acidic, than about 5 pH units. Thus, the process can comprise a testing step to determine whether or not to repeat further the wash to remove residual acid and salt.

The purification processes has been found to be surprisingly effective for the reduction of transition metal contamination. In particular, the purified polymer in a 7 weight percent polymer solution can have iron, chromium, copper or nickel contaminations individually of no more than about 100 parts-per-billion by weight (ppb), in further embodiments no more than about 70 ppb, in further embodiments no more than about 50 ppb and in other embodiments no more than about 25 ppb. With respect to all transition metals in the polymer, the polymer in a 7 weight percent solution can have reduced contaminant levels of no more than about 750 ppb, in further embodiments no more than about 500 ppb, in additional embodiments no more than about 400 ppb, in other embodiments no more than about 200 ppb, in some embodiments no more than about 100 ppb and in further embodiments no more than about 50 ppb. Also, the polymer in a 7 weight percent solution can have metal contamination levels for any individual metal of no more than about 400 ppb and in further embodiments no more than about 300 ppb, in other embodiments no more than about 200 ppb, in additional embodiments no more than about 100 ppb, in some embodiments no more than about 50 ppb and in further embodiments no more than about 25 ppb. A person of ordinary skill in the art will recognize that additional ranges within the explicit ranges above are contemplated and are within the present disclosure.

The filtration purification and acid wash purification can be performed sequentially if desired. The order of purification steps can be selected as desired. Each purification step can also be repeated as desired. Through the combined approaches, various metal contaminant levels can be further reduced.

Subsequent to purification, the polymer can be concentrated, dried, and/or diluted to a desired concentration for further processing or storage. Similarly, the purified polymer can be transferred to a different solvent system. Removal of solvent or portions thereof with respect to quantity or composition of solvent components can comprise evaporation of the solvents with or without heat and with or without application of reduced pressures. In some embodiments, the polymer solution can be designed with a solvent blend that allows for the removal of a solvent component while leaving one or more other solvent components. In some embodiments, the solvent can be removed by evaporation by using, for example, a rotovap or the like. Drying of the polymer can be convenient for storage and/or transportation of the polymer.

In some embodiments, the apparatus cleaning, polymer purification and/or post purification polymer processing can be done in a “clean” environment to help guard against the introduction of contaminants, metal or non-metal, into the polymer. For example, a clean environment can be provided as a clean room, a glove box or the like. Also various processing equipment can be supplied with suitable air filtration or the like, such as HEPA purified rotovaps, which are available from various suppliers.

### Nanoparticles

The desirable silicon-based nanoparticle dispersions described herein are based in part on the ability to form high quality nanoparticles with or without dopants. As described above, laser pyrolysis is a particularly suitable approach for the synthesis of highly uniform silicon submicron particles or nanoparticles. Also, laser pyrolysis is a versatile approach for the introduction of desired dopants at a selected concentration, such as high dopant concentrations. Also, the surface properties of the nanoparticles can be influenced by the laser pyrolysis process, although the surface properties can be further manipulated after synthesis to form desired dispersions. Small and uniform silicon-based particles can provide processing advantages with respect to forming dispersions/inks.

In some embodiments, the particles have an average diameter of no more than about one micron, and in further embodiments it is desirable to have particles with smaller particle sizes to introduce desired properties. For example, nanoparticles with a small enough average particle size are observed to melt at lower temperatures than bulk material, which can be advantageous in some contexts. Also, the small particle sizes provide for the formation of inks with desirable properties, which can be particularly advantageous for a range of coating and/or printing processes since small uniform silicon-based particles can be advantageous for the formation of inks with desirable rheological properties. Generally, the dopants and the dopant concentration are selected based on the desired properties of the subsequently fused material or to provide a desired degree of dopant migration to an adjacent substrate. The dopant concentrations can influence the particle properties also.

In particular, laser pyrolysis is useful in the formation of particles that are highly uniform in composition, crystallinity, and size. A collection of submicron/nanoscale particles may have an average diameter for the primary particles of no more than about 500 nm, in some embodiments from about 2 nm to about 100 nm, alternatively from about 2 nm to about 75 nm, in further embodiments from about 2 nm to about 50 nm, in additional embodiments from about 2 nm to about 40 nm, and in other embodiments from about 2 nm to about 35 nm. A person of ordinary skill in the art will recognize that other ranges within these specific ranges are covered by the disclosure herein. In particular, for some applications, smaller average particle diameters can be particularly desirable. Particle diameters and primary particle diameters are evaluated by transmission electron microscopy. Primary particles are the small visible particulate units visible in the micrograph without reference to the separability of the primary particles. If the particles are not spherical, the diameter can be evaluated as averages of length measurements along the principle axes of the particle.

As used herein, the term “particles” without qualification refers to physical particles, which are unfused, so that any fused primary particles are considered as an aggregate, i.e. a physical particle. For particles formed by laser pyrolysis, if quenching is applied, elemental silicon particles can have a size roughly of the same order of magnitude as the primary particles, i.e., the primary structural element within the material. Thus, the ranges of average primary particle sizes above can also be used with respect to the particle sizes to the extent that fusing is negligible. If there is hard fusing of some primary particles, these hard fused primary particles form correspondingly larger physical particles, and some noteworthy fusing is observed for very small elemental silicon particles with an average primary particle size of less than about 10 nm. The primary particles can have a roughly spherical gross appearance, or they can have non-spherical shapes. Upon closer examination, crystalline particles may have facets corresponding to the underlying crystal lattice. Amorphous particles generally have a spherical aspect.

Because of their small size, the particles tend to form loose agglomerates due to van der Waals and other electromagnetic forces between nearby particles. Even though the particles may form loose agglomerates, the nanometer scale of the particles is clearly observable in transmission electron micrographs of the particles. The particles generally have a surface area corresponding to particles on a nanometer scale as observed in the micrographs. Furthermore, the particles can manifest unique properties due to their small size and large surface area per weight of material. These loose agglomerates can be dispersed in a liquid to a significant degree and in some embodiments approximately completely to form dispersed particles.

The particles can have a high degree of uniformity in size. Laser pyrolysis generally results in particles having a very narrow range of particle diameters. As determined from examination of transmission electron micrographs, the primary particles generally have a distribution in sizes such that at least about 95 percent, and in some embodiments 99 percent, of the particles have a diameter greater than about 35 percent of the average diameter and less than about 280 percent of the average diameter. In additional embodiments, the particles generally have a distribution in sizes such that at least about 95 percent, and in some embodiments 99 percent, of the primary particles have a diameter greater than about 40 percent of the average diameter and less than about 250 percent of the average diameter. In further embodiments, the primary particles have a distribution of diameters such that at least about 95 percent, and in some embodiments 99 percent, of the primary particles have a diameter greater than about 60 percent of the average diameter and less than about 200 percent of the average diameter. A person of ordinary skill in the art will recognize that other ranges of uniformity within these specific ranges are contemplated and are within the present disclosure.

Furthermore, in some embodiments essentially no primary particles have an average diameter greater than about 5 times the average diameter, in other embodiments about 4 times the average diameter, in further embodiments 3 times the average diameter, and in additional embodiments 2 times the average diameter. In other words, the primary particle size distribution effectively does not have a tail indicative of a small number of particles with significantly larger sizes. This is a result of the small reaction region to form the inorganic particles and corresponding rapid quench of the inorganic particles. An effective cut off in the tail of the size distribution indicates that there are less than about 1 particle in 10⁶ has a diameter greater than a specified cut off value above the average diameter. High primary particle uniformity can be exploited in a variety of applications.

High quality particles can be produced that are substantially unfused. However, for the production of very small primary particle sizes, e.g., less than 10 nm average diameter, at higher production rates, the primary silicon particles can involve substantial fusing into a nanostructured material. These particles can still be dispersed into a liquid to produce desired ranges of secondary particle size. Even though the particles with very small primary particle diameters may have significant fusing, these particles may still be desirable for applications in which the small primary particle size and corresponding high surface areas can facilitate dopant delivery and/or fusing of the deposited inks into corresponding structures.

The silicon based nanoparticles can further be characterized by BET surface areas. The surface area measurements are based on gas adsorption onto the particle surfaces. The theory of BET surface area was developed by Brunauer et al., J. Am. Chem. Soc. Vol. 60, 309 (1938). The BET surface area evaluation cannot directly distinguish small particle sizes from highly porous particles, but the surface area measurements nevertheless provide useful characterization of the particles. BET surface area measurements are an established approach in the field, and for silicon particles the BET surface area can be determined with an N₂ gas absorbate. The BET surface area can be measured with commercial instruments, such as a Micromeritics Tristar 3000™ instrument. The silicon based nanoparticles described herein can have BET surface areas ranging from about 100 m²/g to about 1500 m²/g and in further embodiments, from about 200 m²/g to about 1250 m²/g. A person of ordinary skill in the art will recognize that additional ranges within the explicit ranges above are contemplated and are within the present disclosure. The particle diameters can be estimated from the BET surface areas based on the assumption that the particles are non-porous, non-agglomerated spheres.

X-ray diffraction can be use to evaluate the crystallinity of the particles. Furthermore, crystalline nanoparticles produced by laser pyrolysis can have a high degree of crystallinity. For laser pyrolysis synthesis of crystalline silicon particles, it is generally believed that the primary particles correspond with a crystallite. However, x-ray diffraction can also be used to evaluate the crystallite size. In particular, for submicron particles, the diffraction peaks are broadened due to truncation of the crystal lattice at the particle surface. The degree of broadening of the x-ray diffraction peaks can be used to evaluate an estimate of the average crystallite size. While strain in the particles and instrument effects can also contribute to broadening of the diffraction peaks, if the particles are assumed to be essentially spherical, the Scherrer equation, which is well known in the art, can be used to provide a lower limit on the average particle size. Meaningful broadening is only observed for crystallite sizes less than about 100 nm. If the particle sizes from TEM evaluation of primary particle diameters, particle size estimates from the BET surface areas and the particle sizes from the Scherrer equation are roughly equal, this determination provides significant evidence that the fusing of the particles is not excessive and that the primary particles are effectively single crystals. Amorphous or glass particles have very broad x-ray diffraction spectra indicative of a lack of long range order.

The silicon based particles can comprise elemental silicon, silicon oxides, silicon nitrides, silicon oxynitrides and mixtures thereof. In general, silicon oxides can comprise silicon dioxide (SiO₂) or oxygen deficient silicon oxides, e.g., SiOₓ, 0<x<2. Silicon nitrides can be Si₃N₄ or silicon enriched silicon nitride, such as SiNₓ, 0<x<4/3. Silicon oxynitrides can comprise SiNₓO_{y}, x<4/3 and y<2 with 3x+2y≦about 4. A collection of silicon-based nanoparticles can comprise a blend of these silicon-based particles in desired proportions.

In addition, the submicron particles may have a very high purity level. Silicon-based particles can be produced with very low levels of metal impurities using laser pyrolysis with appropriate particle handling procedures. Low metal impurity levels are very desirable from the perspective of semiconductor processing. As described further below, the particles can be placed into dispersions. In the dispersions, processing such as centrifugation can be performed to reduce impurities. In the resulting dispersions, the contamination by metal elements can be very low based on desired handling of the particles. The contaminant levels can be evaluated by ICP-MS analysis (inductively coupled plasma-mass spectrometry).

In particular, the submicron silicon-based particles can be found to have no more than about 1 parts per million by weight (ppm) of metal contaminants, in further embodiments no more than about 900 parts per billion by weight (ppb) and in additional embodiments no more than about 700 ppb of total metal contaminants. For semiconductor applications, iron can be a contaminant of particular concern. With improved particle synthesis, handling and contaminant removal procedures, particles can be dispersed with no more than about 200 ppb of iron, in further embodiments, no more than about 100 ppb and in additional embodiments from about 15 ppb to about 75 ppb of iron contaminants with respect to the particle weight. A person of ordinary skill in the art will recognize that additional ranges of contaminant levels within the explicit ranges above are contemplated and are within the present disclosure. The low contaminant levels allows for the production of particles with low dopant levels of dopants, such as boron or phosphorous, in which the low dopant levels can be effective of tuning the electronic properties of particles in a meaningful way that cannot be achieved at higher contaminant levels.

To achieve the very low contaminant levels, the particles can be synthesized in a laser pyrolysis apparatus sealed from the ambient atmosphere and appropriately cleaned and purged prior to the synthesis. Highly pure gaseous reactants can be used for the silicon precursors as well as for the dopant precursors. Similarly, pure oxygen or ammonia can be introduced as secondary reactants to form silicon oxides or silicon nitrides respectively. The particles can be collected and handled in a glove box to keep the particles free from contaminants from the ambient atmosphere. Very clean polymer containers, such as polyfluoroethylene containers, can be used for placement of the particles. For the formation of inks, the particles can be dispersed in very pure solvents within clean vessels within a glove box or clean room. With meticulous attention to all aspects of the process, the high purity levels described herein have been and generally can be achieved. The production of silicon particles with clean handling procedures is described further in copending U.S. patent application Ser. No. 13/070,286 to Chiruvolu et al., entitled “Silicon/Germanium Nanoparticle Inks, Laser Pyrolysis Reactors for the Synthesis of Nanoparticles and Associated Methods,” incorporated herein by reference.

The size of the dispersed particles in a liquid can be referred to as the secondary particle size. The primary particle size is roughly the lower limit of the secondary particle size for a particular collection of particles, so that the average secondary particle size can be approximately the average primary particle size if the primary particles are substantially unfused and if the particles are effectively completely dispersed in the liquid, which involves solvation forces that successfully overcome the inter-particle forces.

The secondary particle size may depend on the subsequent processing of the particles following their initial formation and the composition and structure of the particles. In particular, the particle surface chemistry, properties of the dispersant, the application of disruptive forces, such as shear or sonic forces, and the like can influence the efficiency of fully dispersing the particles. Ranges of values of average secondary particle sizes are presented below with respect to the description of dispersions. Secondary particles sizes within a liquid dispersion can be measured by established approaches, such as dynamic light scattering. Suitable particle size analyzers include, for example, a Microtrac UPA instrument from Honeywell based on dynamic light scattering, a Horiba Particle Size Analyzer from Horiba, Japan and ZetaSizer Series of instruments from Malvern based on Photon Correlation Spectroscopy. The principles of dynamic light scattering for particle size measurements in liquids are well established. Secondary particles sizes are discussed further below in the context of inks and dispersions. Dopants can be introduced to vary properties of the resulting particles and/or to provide a dopant source supplied by the nanoparticles for migration into adjacent elemental silicon as well as other silicon based materials. In general, any reasonable element can be introduced as a dopant to achieve desired properties. For example, dopants can be introduced to change the electrical properties of the particles, especially silicon. In particular, As, Sb and/or P dopants can be introduced into the elemental silicon particles to form n-type semiconducting materials in which the dopant provide excess electrons to populate the conduction bands, and B, Al, Ga and/or In can be introduced to form p-type semiconducting materials in which the dopants supply holes. In silicon oxides, silicon nitrides and silicon oxynitrides, the dopant elements can be a dopant source for transfer to an adjacent material, such as a silicon wafer. P and B can be provided with respective suitable precursor compounds, such as diborane (B₂H₆) or phosphine (PH₃), which can be provided in very pure gas forms.

In some embodiments, one or more dopants can be introduced into the silicon-based particles, e.g. elemental silicon particles, silica particles, silicon nitride particles and/or silicon oxynitride particles, in concentrations from about 1.0×10⁻⁷ to about 15 atomic percent relative to the silicon atoms, in further embodiments from about 1.0×10⁻⁵ to about 5.0 atomic percent and in further embodiments from about 1×10⁻⁴ to about 1.0 atomic percent relative to the silicon atoms. Both the low dopant levels and the high dopant levels are of interest in appropriate contexts. For the low dopant levels to be of particular usefulness, the particles should be pure with respect to low contamination levels. For small particles, the low dopant levels essentially can correspond with less than one dopant atom per particle on average. In combination with the high purity that has been achieved for the particles, low dopant levels from about 1.0×10⁻⁷ to about 5.0×10⁻³ correspond with difficult to achieve yet potentially useful materials. In some embodiments, high dopant levels are of particular interest, and the highly doped particles can have a dopant concentration from about 0.1 atomic percent to about 15 atomic percent, in other embodiments from about 0.25 atomic percent to about 12 atomic percent, and in further embodiments from about 0.5 atomic percent to about 10 atomic percent. A person of ordinary skill in the art will recognize that additional ranges within the explicit dopant level ranges are contemplated and are within the present disclosure.

### Ink Compositions and Properties

Desirable silicon based nanoparticle inks are formed by processing initial stable dispersions of nanoparticles to adjust the properties to be appropriate for a selected deposition approach. Dispersions of particular interest comprise a dispersing liquid or solvent and silicon based nanoparticles dispersed within the liquid along with a polymer to adjust the ink properties. In appropriate embodiments, silicon based nanoparticles from laser pyrolysis are collected as a powder, and dispersed in a solvent or solvent blend by mixing, although suitable silicon nanoparticles from other sources can be used if of sufficient purity. The dispersion can be stable with respect to avoidance of settling over a reasonable period of time, generally at least an hour or longer, without further mixing. A dispersion can be used as an ink and the properties of the ink can be adjusted based on the particular deposition method. For example, in some embodiments, the viscosity of the ink is adjusted for the use in a particular coating or printing application, and particle concentrations and additives can provide some additional parameters to adjust the viscosity and other ink properties. Screen printing pastes with non-Newtonian rheology are of particular interest, but other inks that incorporate a polymer to adjust the ink properties are also of interest. In some embodiments, the particles can be formed with concentrated dispersions with desirable fluid properties without surface modifying the particles with organic compounds. As noted above, the lack of surface modification with organic compounds excludes references to solvent-based interactions or polymer interactions. In general, the solvents may interact with the particle surfaces with varying degrees of interactions that are distinct from the inclusion of distinct surface modifying agents that form strong and effectively durable chemical modification of the particle surfaces. The availability to form stable dispersions with small secondary particle sizes provides the ability to form certain inks that are not otherwise possible.

Furthermore, it can be desirable for the silicon based nanoparticles to be uniform with respect to particle size and other properties. The formation of a good dispersion with a small secondary particle size can be facilitated through the matching of the surface chemistry of the particles with the properties of the dispersing liquid. The surface chemistry of particles can be influenced during synthesis of the particles as well as following collection of the particles. For example, the formation of dispersions with polar solvents is facilitated if the particles have polar groups on the particle surface.

As described herein, suitable approaches have been found to disperse dry silicon based nanoparticle powders and to form high quality silicon based inks and the like for deposition. In some embodiments, the particle can be surface modified with an organic compound to change the surface properties of the particles in a dispersion, but in some embodiments of particular interest, the particles are not covalently surface modified with an organic compound since the lack of surface modification can provide advantages with respect to properties for certain applications and to simply processing. Thus, for some embodiments, significant advantages are obtained by forming dispersions of particles without surface modification. Using one or more of the processing approaches described herein, inks can be formed that can be deposited using convenient coating and printing approaches based on established commercial parameters. Thus, the advantages of vapor-based particle synthesis can be combined with desirable solution based processing approaches with highly dispersed particles to obtain desirable dispersions and inks, which can be formed with doped particles.

With respect to silicon based nanoparticle dispersions, the dispersions can have nanoparticle concentrations from low concentrations to about 30 weight percent. In general, the secondary particles size can be expressed as a cumulant mean, or Z-average particle size, as measured with dynamic light scattering (DLS). The Z-average particle size is based on a scattering intensity weighted distribution as a function of particle size. The scattering intensity is a function of the particle size to the 6th power so that larger particles scatter much more intensely. Evaluation of this distribution is prescribed in ISO International Standard 13321, Methods for Determination of Particle Size Distribution Part 8: Photon Correlation Spectroscopy, 1996, incorporated herein by reference. The Z-average distributions are based on a single exponential fit to time correlation functions. However, small particles scatter light with less intensity relative to their volume contribution to the dispersion. The intensity weighted distribution can be converted to a volume-weighted distribution that is perhaps more conceptually relevant for evaluating the properties of a dispersion. For nanoscale particles, the volume-based distribution can be evaluated from the intensity distribution using Mie Theory. The volume-average particle size can be evaluated from the volume-based particle size distribution. Further description of the manipulation of the secondary particle size distributions can be found in Malvern Instruments—DLS Technical Note MRK656-01, incorporated herein by reference. As a general matter, due to the scaling of volume average particle sizes by the cube of the particle diameter and the scattering intensity average (Z-average) by the sixth power of the average particle size, these measurements significantly provide emphasis to larger particles over smaller particles.

In some embodiments, the Z-average particle size is no more than about 1 micron, in further embodiments no more than about 250 nm, in additional embodiments no more than about 200 nm, in some embodiments from about 40 nm to about 150 nm, in other embodiments from about 45 nm to about 125 nm, in further embodiments from about 50 nm to about 100 nm. In particular, for some printing applications, it is observed that good printing properties are generally correlated with Z-average particle sizes of no more than about 200 nm. At least for nanoparticles without extremely small primary particle sizes, for dispersions with well dispersed particles and little fusing of the primary particles, the Z-average secondary particle size can be no more than a factor of 5 times the average primary particle size, in further embodiments no more than about 4 times the average primary particle size and in additional embodiments no more than about 3 times the average primary particle size. For primary particles that exhibit some fusing, the absolute value of the Z-average dispersed particle size is still very significant for the processing properties of the silicon based nanoparticle distributions. A person of ordinary skill in the art will recognize that additional ranges of secondary particle sizes within the explicit ranges above are contemplated and are within the present disclosure.

With respect to the particle size distribution, in some embodiment, essentially all of the secondary particles can have a size distribution from scattering results with effectively no intensity corresponding to more than 5 times the Z-average secondary particle size, in further embodiments no more than about 4 times the Z-average particle size and in other embodiments no more than about 3 times the Z-average particle size. Furthermore, the DLS light scattering particle size distribution can have in some embodiments a full width at half-height of no more than about 50 percent of the Z-average particle size. Also, the secondary particles can have a distribution in sizes such that at least about 95 percent of the particles have a diameter greater than about 40 percent of the Z-average particle size and less than about 250 percent of the Z-average particle size. In further embodiments, the secondary particles can have a distribution of particle sizes such that at least about 95 percent of the particles have a particle size greater than about 60 percent of the Z-average particle size and less than about 200 percent of the Z-average particle size. A person of ordinary skill in the art will recognize that additional ranges of particle sizes and distributions within the explicit ranges above are contemplated and are within the present disclosure.

Furthermore, it has been discovered that measurements of dispersion or ink properties, such as through light scattering measurements, of the static dispersion alone does not seem to provide adequate characterization of printing characteristics of the inks. Specifically, rheological measurements also provide significant information related to the deposition characteristics of the inks which can correspond to print quality. Rheology relates to the flow properties of a liquid. Thus, in principle, the rheological measurements provide additional information that is not obtained from the light scattering measurements of a static particle dispersion. Experimental results have been obtained that provide evidence that the rheological measurements provide significant information related to ink properties that are not reflected in light scattering measurements.

Rheological measurements include measurements of viscosity. Viscosity is a measure of a fluid's resistance to shear stress. In general, the rate at which a fluid deforms (i.e. sheer rate) in response to an applied force (i.e. shear stress) determines the viscosity of the fluid being studied. For Newtonian fluids, the viscosity is constant such that the shear rate scales with the shear stress. For non-Newtonian fluids, the viscosity varies non-linearly with the shear stress. An ink's viscosity can be measured using a rheometer. In some embodiments of a rheometer, the liquid to be studied is placed in the annulus between a drive cylinder and a free cylinder. A shear stress is then applied to the ink by rotating the drive cylinder. The moving ink in the annulus, in response to the applied shear stress, causes the free cylinder to begin rotating. The shear rate and, therefore the viscosity of the fluid, can then be calculated from the rotational frequency of the free cylinder. Furthermore, because the applied shear stress can be adjusted by adjusting the rotational frequency of the drive cylinder, a rheometer can be used to obtain the viscosity of non-Newtonian fluids over a wide range of shear stresses. Rheometers are widely available from commercial sources such as Brookfield Engineering Laboratories, Inc. (Middleboro, Mass.).

In general, the surface chemistry of the particles influences the process of forming the dispersion. In particular, it is easier to disperse the particles to form smaller secondary particle sizes if the dispersing liquid and the particle surfaces are compatible chemically, although other parameters such as density, particle surface charge, solvent molecular structure and the like also directly influence dispersability. In some embodiments, the liquid may be selected to be appropriate for the particular use of the dispersion, such as for a printing process. For silicon synthesized using silanes, the resulting silicon generally is partially hydrogenated, i.e., the silicon includes some small amount of hydrogen in the material. It is generally unclear if this hydrogen or a portion of the hydrogen is at the surface as Si—H bonds. However, the presence of a small amount of hydrogen does not presently seem particularly significant. In some embodiments, elemental silicon nanoparticles can become surface oxidized, for example through exposure to air. For these embodiments, the surface can have bridging oxygen atoms in Si—O—Si structures or Si—O—H groups if hydrogen is available during the oxidation process. By preventing exposure to the ambient atmosphere, surface oxidation of the particles can be substantially reduced to no more than about 2 weight percent in the particles. Even without significant oxidation, it is found that elemental silicon nanoparticles formed by laser pyrolysis are suitable for forming good dispersions in appropriately selected solvents without modifying the particles with chemically bonded organic compounds.

In some embodiments, the surface properties of the particles can be modified through surface modification of the particles with a surface modifying composition chemically bonded to the particle surfaces. However, in some embodiments of particular interest, the particles are not surface modified so that unmodified particles are deposited for further processing. In appropriate embodiments, surface modification of the particles can influence the dispersion properties of the particles as well as the solvents that are suitable for dispersing the particles. Some surface active agents, such as many surfactants, act through non-bonding interactions with the particle surfaces, and these processing agents are described further below. In some embodiments, desirable properties, especially dispersability in otherwise unavailable solvents, can be obtained through the use of surface modification agents that chemically bond to the particle surface. The surface chemistry of the particles influences the selection of surface modification agents. The use of surface modifying agents to alter the silicon particle surface properties is described further in published U.S. patent application 2008/0160265 to Hieslmair et al., entitled “Silicon/Germanium Particle Inks, Doped Particles, Printing, and Processes for Semiconductor Applications,” incorporated herein by reference. Any composition for performing surface modification should be provided with appropriately low metal contamination to avoid any undesirable incorporation of metal contaminants into the ink.

While surface modified particles can be designed for use with particular solvents, it has been found that desirable inks can be formed with appropriate solvent selection and processing without surface modification at high particle concentrations and with good deliverability at least in some circumstances. The ability to form desired inks without surface modification can be useful for the formation of desired devices, especially semiconductor based devices, with a lower level of contamination.

The dispersions can be formulated for a selected application. The dispersions can be characterized with respect to composition as well as the characterization of the particles within the dispersions. In general, the term ink is used to describe a dispersion that is subsequently deposited using a coating or printing technique, and an ink may or may not include additional additives to modify the ink properties.

As used herein, stable dispersions have no settling without continuing mixing after one hour. In some embodiments, the dispersions exhibit no settling of particles without additional mixing after one day and in further embodiments after one week, and in additional embodiments after one month. In general, dispersions with well dispersed particles can be formed at concentrations of at least up to 30 weight percent inorganic particles. Generally, for some embodiments it is desirable to have dispersions with a particle concentration of at least about 0.05 weight percent, in other embodiments at least about 0.25 weight percent, in additional embodiments from about 0.5 weight percent to about 25 weight percent and in further embodiments from about 1 weight percent to about 20 weight percent. A person of ordinary skill in the art will recognize that additional ranges of stability times and concentrations within the explicit ranges above are contemplated and are within the present disclosure.

The dispersions can include additional compositions besides the silicon particles and the dispersing liquid or liquid blend to modify the properties of the dispersion to facilitate the particular application. In particular, for screen printing pastes and other inks, polymer additives can significantly improve the printing qualities. Also, other property modifiers can be added to the dispersion to facilitate the deposition process or to influence the ink properties. The inks can be formulated to achieve extremely low metal contamination levels.

In general, polymeric additives can promote desirable ink compositions. Within the ink composition, polymeric additives can function as dispersants, binders, and/or rheology modifiers. As a dispersant, polymeric additives can promote good dispersions by desirably effecting the particle/particle and particle/solvent interactions. As rheology modifiers, polymeric additives can desirably alter the viscosity and/or surface tension of an ink composition. For certain printing applications, such as screen printing, polymer additives can be particularly desirable. For example, using well dispersed ink compositions with appropriately selected rheological properties, screen printing inks can be formulated to inhibit screen clogging during multiple print cycles. Polymer additives can include, for example, polymers with functional groups, such as hydroxide groups, ether groups, ester groups or the like, such that the polymers are soluble in alcohols. Suitable polymers with polar functional groups include, for example, can comprise a cellulose-based polymer, a polyvinyl ester, a polyvinyl alcohol, a polysiloxane polymer or combinations thereof. Cellulose polymers include, for example, cellulose ethers, such as methyl cellulose, ethyl cellulose, hydroxyethyl cellulose, carboxymethyl cellulose, benzyl cellulose and the like. Desirable paste properties resulting from the use of ethyl cellulose is described further in the example below. The purification of the polymers in particular to reduce metal contamination is described in detail above. Blends of different polymer additives can also be used in ink formulations to obtain desired properties.

In general, the one or more polymer additives can be selected to be compatible with the solvent system selected to stabilize the silicon nanoparticle dispersion, while providing desirable rheological properties. In general, the ink can have a polymer additive concentration from about 0.05 weight percent to about 20 weight percent, in other embodiments from about 0.25 weight percent to about 15 weight percent and in further embodiments from about 0.5 weight percent to about 10 weight percent. For the formation of pastes with non-Newtonian rheology, polymer concentrations in the ink are generally from about 0.5 weight percent to about 20 weight percent, in further embodiments from about 1 weight percent to about 15 weight percent and in additional embodiments from about 2 weight percent to about 12 weight percent. For the formation of a Newtonian ink for suitable deposition, the polymer concentrations can be from about 0.05 weight percent to about 1 weight percent, in further embodiments from about 0.075 weight percent to about 0.75 weight percent and in other embodiments from about 0.1 weight percent to about 0.6 weight percent. A person of ordinary skill in the art will recognize that additional ranges of polymer additive concentrations within the explicit ranges above are contemplated and are within the present disclosure.

Other potential additives include, for example, pH adjusting agents, antioxidants, UV absorbers, antiseptic agents and the like. These additional additives are generally present in amounts of no more than about 2 weight percent. A person of ordinary skill in the art will recognize that additional ranges of surfactant and additive concentrations within the explicit ranges herein are contemplated and are within the present disclosure.

For electronic applications, it can be desirable to remove organic components to the ink prior to or during certain processing steps such that the product materials are effectively free from carbon. In general, organic liquids can be evaporated to remove them from the deposited material. However, polymers and other property modifiers may not be removable through evaporation, although they can be removed through heating at moderate temperatures, generally above 200° C., in an oxygen containing atmosphere to combust the organic materials. With respect to polysiloxanes, the organic functional groups can combust upon heating to a suitable temperature to leave behind a silicon oxide material, which can be advantageously used for some of the material processing to introduce desirable properties and/or can be removed at an appropriate time through the use of a silicon oxide etchant.

The viscosity of the dispersion/ink is dependent on the silicon based nanoparticle concentration, the polymer concentration, the nature of the liquids as well as the presence of any other additives. Thus, there are several parameters that provide for adjustment of the viscosity, and these parameters can be adjusted together to obtain overall desired ink properties. In general, a selected coating or printing approach has an appropriate range of viscosity. Surface tension may also be a significant parameter for certain printing applications. For some desired ink formulations, the use of a solvent blend can provide for the rapid evaporation of a low boiling temperature solvent (boiling point approximately no more than about 165° C. and in other embodiments no more than about 160° C.) while using a higher boiling solvent (boiling point at least about 170° C. and in other embodiments at least about 175° C.) to control the viscosity. The high boiling solvent generally can be removed more slowly without excessive blurring of the printed image. After removal of the higher boiling temperature solvent, the printed silicon based nanoparticles can be further processed into the desired device. Suitable printing techniques represent a significant range of desired viscosities from relatively low viscosity for inkjet inks, to moderate viscosities for gravure printing inks and high viscosities for screen print pastes.

In general, increased concentrations of nanoparticles and increased concentrations of polymer can each result in an increase of ink viscosity. A balance of these concentrations can be selected to achieve desired target properties of the deposited ink, although the tradeoffs are not completely commensurate. For example, for some applications it may be desirable to use somewhat lower nanoparticle concentrations as a way to control thicknesses of deposited material following solvent removal and organic combustion. Specifically, the obtain a thinner coating of deposited silicon-based nanoparticles, the ink can be made more dilute with respect to nanoparticles such that a lower coverage of silicon-based particles remains following deposition of a certain amount of ink and drying of the ink. Higher concentrations of polymer can be used to correspondingly increase the ink viscosity, although adjustments of the solvents can also be used to tune the viscosity somewhat. So moderate nanoparticle concentrations can be effective for the deposition of sufficient quantities of silicon-based nanoparticles while maintaining desired rheology and not depositing more material than desired. For example, with screen printing pastes, there are constraints on the printing process in terms of the viscosity of the pastes as well as the practical coating thicknesses. Thus, if a thinner silicon particle deposit is desired, the screen print paste can be made more dilute with nanoparticles so that after the other paste components are removed, the remaining silicon nanoparticle deposit can be thinner based on a smaller quantity of the nanoparticles deposited. The methods described herein can be used to maintain desirable low metal contaminations if the polymer concentration is increased.

Desirable spin-coating ink viscosities and surface tensions can be selected with respect to the desired properties of the target film. Film properties include, but are not limited to, film homogeneity and thickness. For some spin-coating embodiments, the dispersion/ink can have a viscosity from about 0.5 centipoises (cP) to about 150 cP, in further embodiments from about 1 to about 100 cP and in additional embodiments from about 2 cP to about 75 cP. In some embodiments, spin-coating dispersions/inks can have a surface tension from about 20 to about 100 dynes/cm. For some spray coating inks, the viscosity can be from 0.1 cP (mPa·s) to about 100 cP, in other embodiments from about 0.5 cP to about 50 cP and in further embodiments from about 1 cP to about 30 cP. A person of ordinary skill in the art will recognize that additional ranges of viscosity and surface tension within the explicit ranges above are contemplated and are within the present disclosure.

To achieve the target fluid properties, the compositions of the fluids can be correspondingly adjusted. For spray coating inks, the silicon particle concentrations are generally at least about 0.25 weight percent, in further embodiments at least about 2.5 weight percent and in additional embodiments from about 1 weight percent to about 15 weight percent. In some embodiments, the spray coating inks can comprise an alcohol and a polar aprotic solvent. The alcohol can be a relatively low boiling point solvent, such as isopropanol, ethanol, methanol or combinations thereof. In some embodiments, suitable aprotic solvents include, for example, N-methylpyrolidone, dimethylformamide, dimethylsulfoxide, methylethylketone, acetonitrile, ethylacetate and combinations thereof. In general, the ink can comprise from about 10 weight percent to about 70 weight percent alcohol and in further embodiments from about 20 weight percent to about 50 weight percent alcohol. Similarly, the ink can comprise from about 30 weight percent to about 80 weight percent polar aprotic solvent and in additional embodiments form about 40 weight percent to about 70 weight percent polar aprotic solvent. A person of ordinary skill in the art will recognize that additional concentration and property ranges within the explicit ranges above are contemplated and are within the present disclosure.

For screen printing, the formulations are prepared as a paste that can be delivered through the screen. The screens generally are reused repeatedly. The solvent systems for the paste should be selected to both provide desired printing properties and to be compatible with the screens to help avoid screen damaged and/or clogging by the paste. Suitable lower boiling point solvents with boiling points of no more than about 165° C. include, for example, isopropyl alcohol, cyclohexanone, dimethylformamide, acetone or combinations thereof. Suitable higher boiling point solvents with boiling points of at least about 170° C. include, for examples, ethylene glycol, propylene glycol, N-methylpyrrolidone, terpineols, such as α-terpineol, 2-(2-ethoxyethoxy)ethanol (Carbitol), glycol ethers, e.g., butyl cellosolve, or combinations thereof. The screen printing paste can further include a surfactant and/or a viscosity modifier.

In general, the screen printable ink or paste are very viscous at low shear and are non-Newtonian. In particular, the pastes have a high viscosity at low shear and a significantly decreased viscosity at high shear. This non-Newtonian behavior can be used effectively to control the printing process since the paste can be stable on the screen between print cycles and printed with the application of higher shear to deliver the ink through the screen to a substrate.

In some embodiments, the elemental silicon screen printing pastes can have an average viscosity at a shear of 2 s⁻¹, from about 3 Pa·s (Poise) to about 450 Pa·s, in further embodiments from about 4 Pa·s to about 350 Pa·s and in additional embodiments from about 5 Pa·s to about 300 Pa·s. Furthermore, the pastes can have an average viscosity at a shear of 1000 s⁻¹, of no more than about 2 Pa·s, in other embodiments from about 0.001 Pa·s to about 1.9 Pa·s, in further embodiments from about 0.01 Pa·s to about 1.8 Pa·s, and in additional embodiments from about 0.02 to about 1.5 Pa·s. The ratio of low shear to high shear average viscosities is also significant since the screen printing process relies on the change in viscosity. The ratio of low shear average viscosity to high shear average viscosity can be in some embodiments from about 5 to about 500, in further embodiments from about 10 to about 300 and in other embodiments from about 15 to about 200. A person of ordinary skill in the art will recognize that additional ranges of paste rheology parameters within the explicit ranges above are contemplated and are within the present disclosure.

Also, it is desirable for the screen printing paste to not change significantly with repeated printing. In general, the screen is loaded with paste to provide for a significant number of print steps. Printing can be simulated in a rheometer using a high shear period to simulate printing and low shear period to simulate a rest period between printing steps. Specifically, for the purposes of testing this stability, the paste can be subjected to 60 second high shear (1000 s⁻¹) period followed by 200 second low shear (2 s⁻¹) rest period, which is repeated. In general, it is desirable for the average viscosity of the ink during the post-printing rest period to be no less than about 70% of the pre-printing rest period average viscosity, and in further embodiments no less than 80% of the pre-printing ret period average viscosity. Also, after 20 print steps for the average viscosity to be at least about 50%, in some embodiments at least about 75%, in other embodiments at least about 90% of the initial pre-print average viscosity, and in further embodiments at least about the initial pre-print average viscosity. In the Examples below, the average viscosity increases with printing, which may be due to solvent evaporation. Apparatus configurations to reduce or eliminate significant solvent evaporation may further stabilize the paste viscosity with printing. A person of ordinary skill in the art will recognize that additional ranges of paste rheology parameters within the explicit ranges above are contemplated and are within the present disclosure.

The screen printable inks generally can have a silicon particle concentration from about 1 weight percent to about 25 weight percent silicon particles, in further embodiments from about 1.5 weight percent to about 20 weight percent silicon particles, in additional embodiments from about 2 weight percent to about 18 weight percent and in other embodiments from about 2.5 weight percent to about 15 weight percent silicon particles. Also, the screen printable inks can have from 0 to about 10 weight percent lower boiling solvent, in further embodiments from about 0.5 to about 8 and in other embodiments from about 1 to about 7 weight percent lower boiling solvent as well as in some embodiments from about 65 weight percent to about 98 weight percent and in further embodiments from about 70 weight percent to about 95 weight percent higher boiling solvent. Polymer concentrations for non-Newtonian pastes are given above. A person of ordinary skill in the art will recognize that additional ranges of composition for silicon pastes within the explicit ranges above are contemplated and are within the present disclosure.

The property ranges of inks suitable for gravure printing are intermediate between the properties of inkjet inks and screen printing pastes. The properties of gravure inks are described further in the '286 application cited above.

The silicon based nanoparticle inks can have iron, chromium, copper or nickel contamination individually of no more than about 250 parts-per-billion by weight (ppb), in further embodiments no more than about 150 ppb, in additional embodiments no more than about 100 ppb, in other embodiments no more than about 50 ppb and in some embodiments no more than about 25 ppb. In addition, the silicon based nanoparticle inks can have a contamination level for each metal of no more than about 500 ppb, in further embodiments no more than about 400 ppb, in other embodiments no more than about 300 ppb, in additional embodiments no more than about 200 ppb and in some embodiments no more than about 100 ppb. Also, the pastes can have a total transition metal contamination level of no more than about 750 ppb, in additional embodiments no more than about 500 ppb, in further embodiments no more than about 250 ppb, in some embodiments no more than about 200 ppb and in other embodiments no more than about 100 ppb. A person of ordinary skill in the art will recognize that additional ranges of contamination levels in the inks within the explicit ranges above are contemplated and are within the present disclosure.

While the inks can comprise heavily doped silicon based particles, it can be desirable to further include a liquid dopant source in the ink. Suitable liquid dopant sources include, for example, organophosphorus compounds (for example, phosphonates, such as etidronic acid and dimethyl methyl phosphonate, organophosphine oxide, organophosphanes, such as diphenylphosphine, or organophosphates, such as trioctyl phosphate), organoboron compounds (tetraphenylborate or triphenylboron), phosphoric acid, boric acid, combinations thereof or the like. In general, an ink can comprise no more than about 10 weight percent liquid dopant composition as well as any and all subranges within this explicit range.

For dopant drive in applications, it can be desirable to include further components to the ink to facilitate the dopant drive in process. In particular, the ink can comprise a silicon oxide precursor, such as tetraethyl orthosilicate (TEOS). TEOS can be converted to silica in a hydrolysis reaction with water at an appropriate pH. A silica glass can facilitate dopant drive in from highly doped silicon particles into a silicon substrate through the at least partial isolation of the dopants from the vapor phase above the deposited particles and/or to increase solid-phase diffusion pathways to the wafer surface. The alternative or additional use of spin on glasses and silica sol-gels in silicon inks is described in copending U.S. provisional patent application Ser. No. 13/113,287 to Liu et al, entitled “Silicon Substrates With Doped Surface Contacts Formed From Doped Silicon Inks and Corresponding Processes,” incorporated herein by reference.

Also, an elemental silicon nanoparticle ink can further comprise a silica etching agent. A traditional silica wet etching agent comprises an aqueous solution of hydrogen fluoride (HF), which can be buffered with ammonium bifluoride (NH₄HF₂) and/or ammonium fluoride (NH₄F). Hydrogen fluoride is soluble in alcohols, and ammonium fluoride is slightly soluble in alcohols. The concentrations of HF, and optionally of ammonium fluoride, can be selected to achieve the desired silica etching rate for the silicon ink. Note that the silica etching compositions can also be effective at etching thin layers of silicon nitride and silicon oxynitride. When the etching composition is referenced herein, it will be understood that the composition can be effective at these other etching functions even if not specifically mentioned in the context. In some embodiments, the ink can comprise at least about 1 weight percent silica etching agent. The silicon particle concentrations and concentrations of other ink components generally can be selected as described herein for other inks as appropriate for a particular deposition approach. For more rapid etching, the ink can comprise a saturated HF solution. Other useful etchants include, for example, ammonium fluoride, ammonium bifluoride, ethylenediamine-pyrocatechol, ethanolamine-gallic acid, tetraalkyl ammonium hydroxide and combinations thereof.

The silicon nanoparticle inks with the silica etchant can be used to apply doped or undoped silicon nanoparticle deposits onto a silicon substrate where the silicon substrate has an oxide layer, generally silicon oxide. Thus, a separate etching step may be eliminated. The silica etchant can etch through the oxide layer to expose the silicon surface under the oxide layer to the ink. In general, the inks can be deposited using the various coating and printing approaches described herein, such as screen printing, inkjet printing, spin coating, knife edge coating or the like. During further processing, the silica etching agents generally evaporate or decompose into gaseous components with heating to moderate temperatures. Therefore, the compositions can be used to etch through oxide layers and then heated to moderate temperatures to leave a silicon particle coating while evaporating the solvent and correspondingly removing the etchant. In some embodiments, the deposited inks can be heated to temperatures form about 50° C. to about 300° C. to evaporate the solvent and to remove the silica etchant.

Following the drying of the material, a silicon particle coating remains that can be used for dopant delivery and/or to form a silicon mass on a substrate similar to the silicon inks without a silica etchant. Thus, the ink materials with the combination of silica etchant and the silicon nanoparticles can be used to effectively etch through silicon oxide coatings to expose a silicon underlayer that is then in contact with the silicon nanoparticle deposit following drying of the as deposited material. The silicon nanoparticle deposits that remain after drying the ink deposits can be further processed to fuse the silicon nanoparticles and/or drive dopant atoms into the silicon substrate. Further processing to fuse the silicon atoms can be performed generally at a temperature from about 700° C. to about 1200° C.

In other embodiments, silica nanoparticles are combined with the silicon nanoparticles in the ink/dispersion. The relative amounts of silicon nanoparticles and silica nanoparticles can be selected based on the particular application of the ink, and the overall ranges of silicon nanoparticle concentrations described elsewhere herein can apply equally to these blended particle inks. In some embodiments, the ink can comprise at least about 0.01 weight percent silica, in further embodiments from about 0.025 to about 10 weight percent and in other embodiments from about 0.05 to about 5 weight percent silica. In some embodiments, the weight ratio of silica nanoparticles to silicon nanoparticles can be at least about 0.01, in further embodiments from about 0.025 to about 1.5 and in additional embodiments from about 0.05 to about 1. A person of ordinary skill in the art will recognize that additional ranges of silica concentrations and silica to silicon ratios within the explicit ranges above are contemplated and are within the present disclosure. The silicon nanoparticles, the silica nanoparticles, both the silicon nanoparticles and the silica nanoparticles or a portion thereof may be doped. The silica nanoparticles can be used to increase the viscosity of the inks as well as to assist with the formation of a more densely packed deposit that can facilitate dopant drive in.

As described herein, silicon based nanoparticle inks can be formulated for suitable printing processes for commercial applications. In some embodiments, the ability to form good dispersions without chemical modification of the silicon nanoparticle surfaces with an organic compound simplifies processing of the particles after printing. Processing techniques for the inks into corresponding devices can be selected based on the particular application. The ability to form inks with very low metal contaminant levels can in some embodiments directly improve performance of devices formed with the inks. Thus, the availability of the low metal contaminant silicon based nanoparticle inks provides for the applicability of the inks for a broader range of applications.

### Processing to Form Silicon Based Nanoparticle Inks

The processing to form the silicon based nanoparticle inks with a polymer component can be designed to both achieve desired deposition properties as well as to form an ink with very low metal contamination levels. The formation of desirable inks with improved deposition properties can comprise the initial formation of a nanoparticle dispersion that can comprise a strong mixing step, e.g. a sonication step, and a centrifugation step, and in some embodiments, a plurality of one or both of these steps. In particular, it has been found to be useful to perform one or more centrifugation steps to improve the quality of the resulting inks. In some embodiments, the supernatant of a first centrifugation step can be centrifuged a second time with the second supernatant used to form the nanoparticle ink, and the centrifugation process can be repeated a third time or more if desired. Formation of a good initial dispersion of the nanoparticles prior to further processing to form the ink, such as addition of the polymer, can facilitate the subsequent processing steps and can desirably affect the properties of the target ink. The initial dispersion of the as-synthesized particles generally comprises the selection of a solvent that is relatively compatible with the particles based on the surface chemistry of the particles.

In general, it is desirable to have a strong mixing step to facilitate forming a good dispersion of the nanoparticles in combination with a centrifugation step, which is effective both to remove metal contaminants and to remove a portion of the nanoparticles resistant to dispersion. In general, there should be significant mixing prior to performance of the centrifugation so that the centrifugation can be effective. However, additional mixing can be performed after a centrifugation step. Furthermore, there can be a plurality of mixing steps and/or centrifugation steps that are performed in a selected order. Depending on the particle properties, particular particle processing order can be selected to achieve desired dispersion properties. A general discussion of appropriate process follows. Further discussion directed to processing for forming elemental silicon nanoparticle spin coating inks and screen printing pastes is found in copending U.S. patent application Ser. No. 13/353,645 to Li et al., entitled “Silicon/Germanium Nanoparticle Inks and Methods of Forming Inks With Desired Printing Properties,” incorporated herein by reference.

Initial mixing can include mechanical mixing and/or sonication mixing. Mechanical mixing can include, but is not limited to, beating, stirring, and/or centrifugal planetary mixing. In some embodiments, centrifugal planetary mixing has been shown to be particularly effective as a mechanical mixing approach in reducing particle agglomeration, although other initial mixing methods can also desirably reduce particle agglomeration. The procedure for performing the initial mixing can significantly influence the concentration of the resulting ink. In particular, the initial mixing step influences the amount of particulates that remain suspended following a subsequent centrifugation step. Initial mixing can comprise a plurality of distinct mixing steps, which may or may not be similar in quality.

In centrifugal planetary mixing, the material to be mixed is placed in a container that is rotated about its own axis and the container itself rotates around another axis of the mixer to generate a spiral convection to mix the contents of the container. The mixer provides strong mixing conditions without the application of strong shear, such as in a twin screw extruder. Centrifugal planetary mixers are available from commercial sources such as THINKY USA, Inc. (Laguna Hills, Calif.). In some embodiments, a mixture of as-synthesized particles and solvent is initially mixed in a centrifugal planetary mixer at between about 200 rpm to about 10,000 and, in other embodiment, from about 500 rpm to about 8000 rpm. In some embodiments, a mixture as as-synthesized particles initially mixed in a centrifugal planetary mixer, for example, for up to about an hour and, in other embodiments, from about 1 min. to about 30 min. A person of ordinary skill in the art will recognize that additional ranges of centrifugation frequencies and times are within the explicit ranges herein are contemplated and are within the present disclosure.

Sonication generally can include, but is not limited to, bath sonication, probe sonication, ultrasonic cavitation mixing, combinations thereof or the like. Sonication processes involve the propagation of sound waves, generally at ultrasonic frequencies, that result in cavity formation in the liquid and the violent collapse of the resulting bubbles. A range of commercial sonication devices are available. Bath and probe sonication can also allow for convenient temperature control during initial mixing by controlling the temperature of the surrounding bath, such as performing the sonication at reduced temperatures. In some embodiments, a mixture is sonicated for no more than about 20 hrs, in other embodiments for no more than about 5 hrs, and in further embodiments from about 5 min. to about 30 min. A person of ordinary skill in the art will recognize that additional ranges of sonication times are within the explicit ranges herein are contemplated and are within the present disclosure.

In general, the dispersion can be centrifuged to improve the properties of the dispersion. It has been found that centrifugation of nanoparticle dispersions can be useful for the formation of the highly pure dispersions with very low metal contamination described herein. The centrifugation parameters can be selected such that at least a reasonable fraction of the silicon based nanoparticles remain dispersed, but contaminants and more poorly dispersed solid components settle to the bottom of the centrifuge container.

To obtain greater improvement in the dispersion properties, centrifugation can comprise multiple centrifugation steps, with each subsequent step performed with the same or different centrifugation parameters as the preceding step. In some embodiments, after each centrifugation step, the supernatant can be decanted or similarly separated from the settled contaminants and subsequently centrifuged in the subsequent centrifugation step. Additional mixing or other processing steps can be performed between centrifugation steps for embodiments involving multiple centrifugation steps. After centrifugation for further processing or use of the inks, the supernatant can be decanted or similarly separated from the settled contaminants for further processing. In some embodiments, a dispersion is centrifuged at 3000 revolutions per minute (rpm) to 15000 rpm, in further embodiments from about 4000 rpm to about 14000 rpm and in other embodiments form about 5000 rpm to about 13000 rpm. In some embodiments, a dispersion is centrifuged for about 5 minutes to about 2 hours, in further embodiments from about 10 minutes to about 1.75 hours and in other embodiments from about 15 minutes to about 1.5 hours. A person of ordinary skill in the art will recognize that additional ranges of centrifugation frequencies and times are within the explicit ranges herein are contemplated and are within the present disclosure.

After centrifugation, it can be desirable to further subject the dispersion to a post-centrifugation sonication. It has been found that sonication after centrifugation can aid in formation of a higher quality ink for some silicon based nanoparticles. Post-centrifugation sonication can comprise one or more selected forms of sonication as described above. With respect to post-centrifugation bath sonication, in some embodiments a dispersion is sonicated for no more than about 5 hr., in other embodiments from about 5 min. to about 3.5 hr, in further embodiments from about 10 min. to about 2 hr., and in yet other embodiments, from about 15 minutes to about 1.5 hr. A person of ordinary skill in the art will recognize that additional ranges within the explicit ranges above are contemplated and are within the present disclosure. Post-centrifugation sonication can be performed at the temperature ranges and with sonication frequencies as discussed above. Whether or not the ink is subjected to post-centrifugation sonication, the ink can be subjected to centrifugal planetary mixing or the like to homogenize the sample.

The particular additives can be added in an appropriate order to maintain the stability of the particle dispersion. In general, the additives can be added after centrifuging the silicon nanoparticle dispersion. Some mixing is performed to disburse the additive through the ink composition. A person of ordinary skill in the art can select the additives and mixing conditions empirically based on the teachings herein.

While in principle, a polymer and dry nanoparticles can be added to a liquid and then subjected to strong mixing conditions, it is generally desirable to first form a good dispersion of the nanoparticles prior to adding the polymer to obtain better dispersion of the nanoparticles. Also, a polymer can be added as a dry material to the nanoparticle dispersion, but processing generally can be facilitated by also dissolving the polymer prior to combining the polymer solution with the nanoparticle dispersion. After combining the polymer solution with the nanoparticle dispersion suitable mixing can be applied.

For particular applications, there may be fairly specific target properties of the inks as well as the corresponding liquids used in formulating the inks. At an appropriate stage in the dispersion process, it can be desirable to change the solvent in the dispersion. It can also be desirable to increase the particle concentration of a dispersion/ink relative to an initial concentration used to form a good dispersion.

Solvent compositions can be generally changed at any convenient point in the processing as well as at multiple points in the overall processing. For example, in some embodiments, a solvent blend at a selected concentration can be formed between the initial mixing step and the centrifugation step, while in other embodiments a solvent blend can be formulated after a centrifugation step before a post-centrifugation sonication step. Also, additional mixing steps can be included in combination with the solvent changes, and solvent modification can be performed between multiple centrifugation steps. One approach for changing solvents involves the addition of a liquid that destabilizes the dispersion. The liquid blend then can be substantially separated from the particles through decanting or the like. The particles are then re-dispersed in the newly selected liquid. This approach for changing solvents is discussed in published U.S. patent application 2008/016065 to Hieslmair et al., entitled “Silicon/Germanium Particle Inks, Doped Particles, Printing and Processes for Semiconductor Applications,” incorporated herein by reference.

With respect to the increase of particle concentration, solvent can be removed through evaporation to increase the concentration. This solvent removal generally can be done appropriately without destabilizing the dispersion. A lower boiling solvent component can be removed preferentially through evaporation. A combination of evaporation and further solvent addition can be used to obtain a target solvent blend. Solvent blends can be particularly useful for the formation of ink compositions since the blends can have multiple liquids that each contribute desirable properties to the ink. In some embodiments, a low boiling temperature solvent component can evaporate relatively quickly after printing to stabilize the printed ink prior to further processing and curing. A higher temperature solvent component can be used to adjust the viscosity to limit spreading after printing. Thus, for many printing applications, solvent blends are desirable. The overall solvent composition can be adjusted to yield desired ink properties and particle concentrations.

For appropriate embodiments, the design of a solvent blend can be based on the ability to maintain a good dispersion after the initial formation of the dispersion. Thus, a desirable approach for the formation of inks with desired properties is to form a good dispersion of the particles and to maintain the good dispersion of the particles through the blending of solvents. The blend of solvents is selected such that the different liquids combine to form a single phase through the miscibility or solubility of the liquids with respect to each other. In some embodiments, it can be desirable to form dispersions by initially dispersing the as-synthesized particles in a blend of solvents. In some embodiments, an additional solvent can be added to the dispersion after initial mixing. Generally, a solvent can be added to a dispersion without destabilizing the dispersion. However, it can also be desirable to further mix a dispersion after addition of a solvent.

### Ink Deposition and Processing

The silicon based nanoparticle inks can be deposited using a selected approach that achieves a desired distribution of the dispersion on a substrate. The inks of particular interest comprise a polymer, and silicon based nanoparticle pastes are of particular interest. In general, various coating and printing techniques can be used to apply the ink to a surface. Coating methods can be particularly efficient for uniformly covering large surface areas with an ink in a relatively short amount of time. Using selected printing approaches, patterns can be formed with moderate resolution. In some embodiments, coating and/or printing processes can be repeated to obtain a thicker deposit of ink and/or to form overlapping patterns. Suitable substrates include, for example, polymers, such as polysiloxanes, polyamides, polyimides, polyethylenes, polycarbonates, polyesters, combinations thereof, and the like, ceramic substrates, such as silica glass, and semiconductor substrates, such as silicon or germanium substrates. The composition of the substrates influences the appropriate range of processing options following deposition of the dispersion/ink as well as the suitable application for the resulting structure. Following deposition, the deposited material can be further processed into a desired device or state. For many applications it is desirable to use a silicon substrate. Suitable silicon substrates include, for example, silicon wafers, which can be cut from silicon ingots, or other silicon structures, such as those known in the art. Silicon wafers are commercially available. In other embodiments, suitable substrates include, for example, various thin sheets of silicon/germanium such as foils, as described in published U.S. Patent application 2007/0212510A to Hieslmair et al., entitled “Thin Silicon or Germanium Sheets and Photovoltaics Formed From Thin Sheets,” incorporated herein by reference.

Each printing/coating step may or may not involve a patterning. The ink may or may not be dried or partially dried between the respective coating and/or printing steps. Sequential patterned printing steps generally involve the deposition onto an initially deposited ink material. The subsequent deposits may or may not approximately align with the initially deposited material, and further subsequently deposited patterns of material may or may not approximately align with the previously deposited layers. Thus, multiple layers can be present only at a subset of the ink deposit. To obtain desired thickness of deposited inks, a coating or printing process can be repeated to form multiple layers of the ink with a corresponding greater thickness. In some embodiments, the printing/coating can be repeated for a total of two printing/coating steps, three printing/coating steps, four printing/coating steps or more than four printing/coating steps. However, polymers can be used to form an ink with a reduced nanoparticle loading to reduce the thickness of a printed deposit following drying and the removal of organic components.

Suitable coating approaches for the application of the dispersions include, for example, spin coatings, dip coating, spray coating, knife-edge coating, extrusion or the like. In general, any suitable coating thickness can be applied, although in embodiments of particular interest, coating thickness can range from about 10 nm to about 500 microns, in some embodiments from about 25 nm to about 400 microns and in further embodiments from about 50 nm to about 250 microns. A person of ordinary skill in the art will recognize that additional ranges of thicknesses within the particular ranges above are contemplated and are within the present disclosure. The ranges of thicknesses similarly can be applied using printing techniques that may only cover a portion of a substrate.

Spin coatings involves the deposition of an ink onto at least a portion of substrate and spinning the substrate to coat the substrate surface with the deposited ink. The rotational frequency of the substrate as well as the spin coating time can be selected with reference to the ink viscosity as well as the desired uniformity and thickness of the resulting coating. The substrate can be spun at a single rotational frequency or it can be spun at successively different frequencies for the same or for a different amount of time.

In knife-edge coating, a substrate is coated by depositing an ink onto the substrate surface with a selected thickness such that the dried and/or further processed coating has an ultimate desired thickness of the coating. The inks for knife edge coating can be relatively viscous, and the inks comprising polymers described herein can be useful for knife edge coating application. A sharp edge is suspended over the substrate so that distance between the edge of the knife and the substrate surface corresponds to the selected initial thickness of the coating. The substrate is then moved relative to the knife such that as the substrate moves past the blade, the deposited ink is reduced to the desired thickness. Substrate movement rates can be selected based upon the desired quality of the formed film as well as on ink characteristics. For example, a coating rate that is too high can undesirably affect the formed coating due to an undesirable increase in ink pressure as it passes under the knife edge. Slower coating rates result in longer residence time of the ink on the surface and can lead to undesirable evaporation of solvent from ink prior to moving passed the knife edge. The selection of the substrate movement rate is based upon a balance of these and other factors, including but not limited to, desired coating thickness, ink viscosity, and knife blade geometry.

Similarly, a range of printing techniques can be used to print the dispersion/ink into a pattern on a substrate. Suitable printing techniques include, for example, screen printing, inkjet printing, lithographic printing, gravure printing and the like. The selection of the printing technique can be influenced by a range of factors including, for example, capital costs, ease of incorporation into an overall production process, processing costs, resolution of the printed structure, printing time and the like. The inks comprising a polymer as described herein are particularly effective for screen printing pastes.

Screen printing can offer desirable features for printing silicon inks for some applications. Screen printing apparatuses are commercially available and are widely used for various applications involving moderate resolution. The silicon particles and processes described herein are suitable for forming good quality pastes for screen printing as demonstrated in the examples below. In a screen printing process, the screen printing paste generally has a high low shear viscosity. Thus, the paste is stable in a reservoir between printing steps. During a printing step high shear is applied to force the paste through the screen for printing. With the application of high shear, the non-Newtonian paste has a significantly reduced viscosity so that the paste can effectively flow through the screen. At the end of the printing process, the paste rests again without the application of shear.

In general, following deposition, the liquid evaporates to leave the silicon based nanoparticles and any other non-volatile components of the inks remaining. For some embodiments with suitable substrates that tolerates suitable temperatures and with organic ink additives, if the additives have been properly selected, the additives can be removed through the addition of heat in an appropriate atmosphere to remove the additives, as described above. Once the solvent and optional additives are removed, the silicon based particles can then be processed further to achieve desired structures from the particles.

For example, if the silicon based nanoparticles comprise elemental silicon, the deposited nanoparticles can be melted to form a cohesive mass of the silicon deposited at the selected locations. If a heat treatment is performed with reasonable control over the conditions, the deposited mass does not migrate significantly from the deposition location, and the fused mass can be further processed into a desired device. The approach used to sinter the silicon particles can be selected to be consistent with the substrate structure to avoid significant damage to the substrate during silicon particle processing. For example, laser sintering or oven based thermal heating can be used in some embodiments. Laser sintering and thermal sintering of silicon nanoparticles is described further in published U.S. patent application 2011/0120537 to Liu et al., entitled “Silicon Inks for Thin Film Solar Cell Formation, Corresponding Methods and Solar Cell Structures,” incorporated herein by reference. The use of highly doped silicon nanoparticles for dopant drive in applications is described further below.

### Semiconductor Applications

The silicon based nanoparticle inks are well suited for a range of applications in which low metal contamination is significant, such as formation of solar cell components, electronic circuit components or the like. In some embodiments, the ability to deliver highly doped elemental silicon with a low contamination level provides the ability to form components with good electrical properties with moderate resolution. In particular, doped inks can be used to form doped contacts for crystalline silicon solar cells. Similarly, the inks can be used to form components of thin film transistors. Upon deposition and drying of the inks, the resulting nanoparticle deposits can be processed into densified silicon structures. Other silicon nanoparticle compositions can be used for dopant delivery and/or for dielectric components in similar types of applications in which metal contamination is undesirable.

For solar cell, thin film transistor and other semiconductor applications, silicon particles can be used to form structures, such as doped elements, that can form a portion of a particular device. For particular applications, patterning or no patterning can be used as desired for a particular application. In some embodiments, the inks can be used to form layers or the like of doped or intrinsic silicon. The formation of silicon layers can be useful for formation or thin film semiconductor elements, such as on a polymer film for display, layers for thin film solar cells or other applications, or patterned elements, which can be highly doped for the introduction of desired functionality for thin film transistors, solar cell contacts or the like. In particular, doped silicon inks are suitable for printing to form doped contacts and emitters for crystalline silicon based solar cells, such as for selective emitter or back contact solar cell structures.

The formation of a solar cell junction can be performed, for example, using the screen printing of an elemental silicon ink with thermal densification in which the processing steps are folded into an overall processing scheme. In some embodiments, doped silicon particles can be used as a dopant source that provides a dopant that is subsequently driven into the underlying substrate to for a doped region extending into the silicon material. Following dopant drive-in, the silicon particles may or may not be removed. Thus, the doped silicon particles can be used to form doped contacts for solar cells. The use of doped silicon particles for dopant drive-in is described further in copending U.S. patent application Ser. No. 13/113,287 to Liu et al (the “'287 application”), entitled “Silicon Substrates With Doped Surface Contacts Formed From Doped Silicon Inks and Corresponding Processes,” incorporated herein by reference.

For crystalline silicon based solar cells, doped silicon based inks can be used to provide dopants for the formation of doped contacts and emitters along both surfaces of the cell or along the back surface of the cell, i.e., back contact solar cells. The doped contacts can form local diode junctions that drive collection of a photocurrent. Suitable patterning can be accomplished with the inks. Some specific embodiments of photovoltaic cells using thin semiconductor foils and back surface contact processing is described further in published U.S. patent application 2008/0202576 to Hieslmair (the '576 application), entitled “Solar Cell Structures, Photovoltaic Panels, and Corresponding Processes,” incorporated herein by reference.

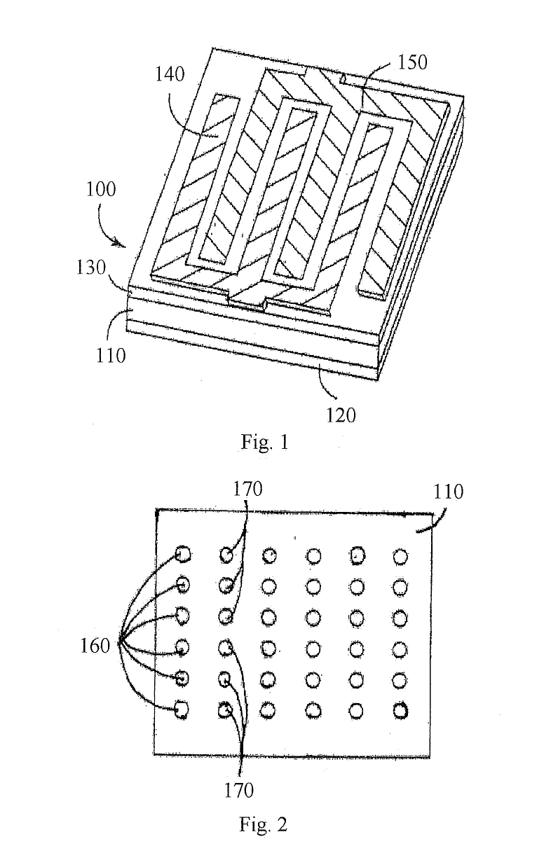

Referring to FIGS. 1 and 2, a representative embodiment of an individual photovoltaic cell is shown. The photovoltaic cell in these figures is a back contact only cell, although the inks described herein can be effectively used for other photovoltaic cell designs. Photovoltaic cell 100 comprises a semiconductor layer 110, a front surface passivation layer 120, a rear surface passivation layer 130, negative current collector 140, and positive current collector 150. FIG. 2 is a bottom-view of photovoltaic cell 100, showing only the semiconducting layer with deposited n-doped islands 160 and p-doped islands 170. For clarity, only the first two columns of doped islands are labeled, however successive columns are analogously doped with alternating dopant type. Collector 140 generally is in electrical contact with n-doped islands 160. Collector 150 generally is in electrical contact with p-doped islands 170. Holes can be created through rear surface passivation layer 130 in alignment with the doped islands 150, 160 and filed with current collector material to make electrical contact between doped islands 160, 170 and corresponding current collectors 140, 150. Each current collector has sections along opposite edges of the cell to connect the columns and to provide for connection of the current collectors. Other selected patterns can be used for the doped contacts in which the pattern provides for connections of commonly doped contacts with non-overlapping current collectors.

The '576 application describes forming shallow doped regions in some embodiments. These shallow doped regions can be conveniently formed by printing the doped silicon and using heat and/or light, such as from a laser or flash lamp, to fuse the doped silicon into corresponding doped contacts. This processing can further lead to dopant drive-in to supply dopant in the initial silicon material. Also, the doped silicon particles described herein can be also used to deliver the dopant atoms to the underlying silicon substrate. Also, other similar solar cell elements can be formed on other silicon or other semiconducting substrates for solar cell applications. Dopant drive-in and silicon particle fusing is described further in the '287 application cited above. If the silicon based nanoparticles are used solely as a dopant source, some or all of the remains of the particles can be removed following processing if desired. Nanoparticles can be removed following processing using, for example, suitable etching agents, which are known in the art.

The inks can be effectively used to form thin film solar cells. In particular, nanocrystalline silicon can absorb significantly more visible light for a given thickness of material compared with highly crystalline silicon. In particular, for thin film solar cells, a stack with layers of p-type and n-type silicon are deposited, optionally with an intrinsic silicon layer between the doped layers to form a p-(i)-n diode junction across the cell. A plurality of stacks can be used if desired. The silicon inks described herein can be used to form one or more of the layers or portions thereof. The formation of thin film solar cells with silicon inks is described further in published U.S. patent application 2011/0120537 to Liu et al., entitled “Silicon Inks for Thin Film Solar Cell Formation, Corresponding Methods and Solar Cell Structures,” incorporated herein by reference.

The silicon based inks can also be used for the formation of integrated circuits for certain applications. Thin film transistors (TFTs) can be used to gate new display structures including, for example, active matrix liquid crystal displays, electrophoretic displays, and organic light emitting diode displays (OLED). Appropriate elements of the transistors can be printed with silicon based inks using conventional photolithographic approaches or for moderate resolution using screen printing or other suitable printing techniques. The substrates can be selected to be compatible with the processing temperatures for the ink. TFTs comprise doped semiconductor elements and corresponding interfaces. For example, thin film transistors used as electronic gates for a range of active matrix displays are described further in Published U.S. Patent Application number 2003/0222315A to Amundson et al., entitled “Backplanes for Display Applications, and Components for use Therein,” incorporated herein by reference. Similarly, the use of a plurality of TFTs in a display device is described in U.S. Pat. No. 8,188,991 to Ohhashi et al., entitled “Display Device and Driving Method Thereof,” incorporated herein by reference.

To form a device component from the silicon based nanoparticle deposit, the material can be heated. For example, the structure can be placed into an oven or the like with the temperature set to soften the particles such that fuse into a mass. This can be done, for example, by heating the substrate in an oven to relatively high temperatures, such as about 750° C. to 1250° C. to obtain a solid mass from the particles in intimate contact with the substrate surface. The time and temperature can be adjusted to yield a desired fusing and corresponding electrical properties of the fused mass. Appropriate approaches can be used to heat the surface of the substrate with the deposit. The heating of a silicon wafer with silicon based nanoparticle ink coating in an oven or with a laser to form a fused mass is described further in the '287 application cited above. In alternative embodiments, a flash lamp, infrared lamp or the like can be used to provide rapid thermal processing of deposited silicon based nanoparticles. Thermal and light based fusing of silicon particles is described further in the '286 patent application cited above.

### EXAMPLES

### Example 1

### Purification of Ethyl Cellulose

This Example demonstrates the purification of ethyl cellulose (EC) using either an acid wash procedure or filtration. This Example also demonstrates the effect of EC solution viscosity and the use of multiple filters in EC purification by filtration.

To demonstrate EC purification, EC samples were prepared by either an acid wash or filtration procedure. The acid wash procedure comprised initially forming a 1-10 wt % EC solution by dissolving an appropriate amount of commercial EC (Sigma-Aldrich) in ethanol and mixing the resulting solution. The solution was then centrifuged and the supernatant was decanted into a clean centrifuge bottle, to remove any particulate matter. A solution of either 10% HCL or 10% acetic acid was added to the supernatant to form a 1:3-1:1 acidified solution of acid:EC+ethanol, and the acidified dispersion was mixed and sonicated for between 30 minutes to 3 hours to form a slurry. The acidified dispersion had a pH in the range of about 1-3 pH units. The addition of the aqueous acid precipitates the polymer such that further centrifugation results in a polymer precipitate with the appearance or a powder or crushed pellet. The slurry was centrifuged and the supernatant, comprising a solution of salt and acid, was decanted into a waste container. The solid phase was re-suspended by adding de-ionized water to the solid phase and mixing to form a second slurry. The second slurry was centrifuged, and the pH of the supernatant was checked. If the pH was less than 5, the process of decanting the supernatant, adding di-ionized water and centrifuging was repeated until the supernatant had a pH greater than about 5. After the supernatant had a pH greater than about 5, it was decanted, and the solid ethyl cellulose precipitate was dried on a hotplate or vacuum oven until substantially all the moisture was removed.

The filtration procedure comprised initially dissolving with mixing an appropriate amount of commercial EC in acetone to form a solution. Subsequently, for some samples terpineol was added to the solution and mixed. The resulting EC solution was then centrifuged and the supernatant, containing the EC, was decanted into a clean bottle. A further amount of acetone was then added to the supernatant and mixed to form a filtration solution at a desired concentration. The filtration solution was subjected to one or more filtration steps. During each filtration step, the filtration solution was filtered under moderate pressure through a filtration assembly having one or more filters. If a plurality of filters were used, the subsequent filters could have the same or different pore sizes as a previous filter. Prior to each filtration, the filters were cleaned by filtering an appropriate amount of acetone through the filtration assembly at moderate pressure. Following the last filtration step, the filtrate was rotovaped to remove acetone and the resulting EC/terpineol solution was transferred to a clean bottle. We note that the terpineol was not removed because it is used in the formulations described below. However, the terpineol can be removed, if desired, using appropriate, solid-fluid separation methods known in the art. Terpinol may or may not be included for the formation of subsequent inks comprising terpinol, but the EC purification can be performed without the addition of terpineol for the formation of the purified EC.

To compare the effectiveness of the two different purification approaches, 5 samples were formed. Sample 1 comprised commercial EC without purification, samples 2 and 3 comprised EC purified by filtration and sample 5 comprised EC purified by acid wash with acetic acid. EC purification in samples 2 and 3 incorporated 3 (sample 2) or more (sample 3) filters in the filtration assembly. The concentration of metal contaminants each sample was measured by inductively coupled plasma-mass spectrometry (“ICP-MS”) and the results are displayed in Table 1, below. All metal concentrations are reported in parts per billion (“ppb”) by weight. With respect to samples 1, 4 and 5, ICP-MS measurements were made on solutions of purified EC in terpineol. With respect to sample 1, the EC/terpineol solution comprised 1.5 wt % EC and the results were linearly scaled to predict contamination concentrations in a 7 wt % EC solution. With respect to samples 4 and 5, 7 wt % EC/terpineol solutions were formed. As described above, after filtration purification, the purified EC was collected as a solution of EC in Terpineol; the solutions were 7 wt % Terpineol.

TABLE 1

| | | | | | | Acid |
|---|---|---|---|---|---|---|
| | | | | | Acid | Wash |
| | | Unpurified | | | Wash | (Acetic |
| | | Sample 1 | Filtration | | (HCl) | Acid) |
| | | 7% EC | Sample | Sample | Sample | Sample |
| | | (calc. from | 2 | 3 | 4 | 5 |
| | | 1.5% EC) | 7% EC | 7% EC | 7% EC | 7% EC |
| Aluminum | (Al) | 8.1 | 44 | 16 | 7.9 | 7.3 |
| Barium | (Ba) | 48.8 | 24 | 7.9 | 0.75 | 3.2 |
| Calcium | (Ca) | 1770.5 | 710 | 94 | 110 | 120 |
| Chromium | (Cr) | 41.6 | 7.9 | 6.1 | 7.3 | 5.7 |
| Copper | (Cu) | 100.4 | 15 | 0.8 | 7.9 | 18 |
| Iron | (Fe) | 426.1 | 140 | 46 | 13 | 37 |
| Magnesium | (Mg) | 361.6 | 120 | 19 | 11 | 19 |
| Nickel | (Ni) | 1165.0 | 230 | 81 | 150 | 280 |
| Potassium | (K) | 233.5 | 14 | 7.3 | 92 | 46 |
| Sodium | (Na) | 84990.2 | 58 | 9.6 | 47 | 42 |
| Titanium | (Ti) | 36.0 | 5.3 | 3.6 | 11 | 19 |
| Zinc | (Zn) | 51.8 | 25 | 21 | 33 | 35 |

| | | | | | |
|---|---|---|---|---|---|
| Total Transition | 1820.9 | 423.2 | 154.9 | 211.2 | 394.7 |
| Metal | | | | | |
| Concentration | | | | | |

Referring to Table 1, the results demonstrate that for the samples tested, purification by either filtration or acid was generally significantly effective in reducing the metal concentration relative to commercial EC. In particular, samples 2 and 3 (filtration) and samples 4 and 5 (acid wash) had greatly reduced transition metal concentrations relative to sample 1. With respect to the samples prepared from filtered EC, sample 3 had Fe and Cu concentrations of less than about 50 ppb and 1 ppb, respectively, and a total transition mental concentration of less than about 160 ppb. With respect to the samples prepared from acid washed EC, samples 4 and 5 had a Fe and Cu concentration of less than less than 40 ppb and 20 ppb, respectively, and a total transition metal concentration of less than about 395 ppb. Additionally, comparison of the metal concentrations between samples 2-4 and samples 5 and 6 reveal that the acid wash procedure was significantly more effective in reducing Fe concentration while filtration was moderately more effective in reducing Cu concentration. However, Cu concentration in samples 4 and 5 were still low. In all cases, purification with either filtration or acid wash significantly reduced the Na concentration relative to the sample comprising commercial EC.

The effect of concentration on EC purification by filtration after acid wash process was also tested. To demonstrate the effect of the combination of the two purification process, concentration another sample (Sample 6) was prepared as described above for the acid wash and filtration purification samples. The metal concentration in sample 6 was measured by ICP-MS and the results are displayed in Table 2 with metal concentrations reported in ppb by weight. Comparison of Tables 1 and 2 demonstrate that there is a significant reduction in metal levels, specially Ni level.

TABLE 2

| | | Sample 6 |
|---|---|---|
| | | Acid wash and filtration |
| | | 7% EC |
| Aluminum | (Al) | 23 |
| Barium | (Ba) | 0.47 |
| Calcium | (Ca) | 53 |
| Chromium | (Cr) | 5.3 |
| Copper | (Cu) | 0.72 |
| Iron | (Fe) | 16 |
| Magnesium | (Mg) | 15 |
| Nickel | (Ni) | 3.0 |
| Potassium | (K) | 21 |
| Sodium | (Na) | 28 |
| Titanium | (Ti) | 6.4 |
| Zinc | (Zn) | 2.8 |

| | |
|---|---|
| Total Transition Metal Concentration | 28 |

Another example of purification of other commercial available EC was performed. Sample 7-10 were prepared with EC from Ashland. The concentration of metal contaminants in the EC was measured by ICP-MS and the results are presented in Table 3 in ppb by weight. Table 3 shows metal levels of sample 7 after filtration, sample 8 after single acid wash, sample 9 after double acid wash, and sample 10 after single acid wash and filtration. There was slightly improvement (i.e. reduction) in metal levels after double acid wash compared to single acid wash. Iron was removed significantly after acid wash. The filtration process helped to remove Ni to lower than 10 ppb.

TABLE 3

| | | | | Sample 9 | Sample 10 |
|---|---|---|---|---|---|
| | | Sample 7 | Sample 8 | Double acid | Acid wash and |
| | | Filtration | Acid wash | wash | filtration |
| | | EC-7% | EC-7% | EC-7% | EC-7% |
| Aluminum | (Al) | 17 | 4.7 | 4.7 | 7.4 |
| Barium | (Ba) | 3.8 | 0.39 | 0.40 | 0.094 |
| Calcium | (Ca) | 210 | 14 | 11 | 7.6 |
| Chromium | (Cr) | 5.7 | 8.3 | 6.4 | 2.9 |
| Copper | (Cu) | 0.46 | 4.5 | 2.2 | 0.35 |
| Iron | (Fe) | 25 | 18 | 13 | 11 |
| Magnesium | (Mg) | 35 | 4.4 | 3.9 | 2.8 |
| Nickel | (Ni) | 11 | 120 | 100 | 1.1 |
| Potassium | (K) | 12 | 7.8 | 7.2 | 3.9 |
| Sodium | (Na) | 34 | 44 | 55 | 6.8 |
| Titanium | (Ti) | 4.8 | 40 | 88 | 3.3 |
| Zinc | (Zn) | 3.3 | 34 | 16 | 1.5 |

| | | | | |
|---|---|---|---|---|
| Total Transition | 40 | 177 | 131 | 14 |
| Metal | | | | |
| Concentration | | | | |

### Example 2

### Impurities in Si Nanoparticle Dispersions

This example demonstrates the range and quantities of metal impurities in Si dispersions.

To test the range and quantities of impurities in Si inks, dispersions were formed, all with phosphorous doped silicon particles. The silicon particles were formed with and without high levels of doping using laser pyrolysis as described in Example 2 of published U.S. patent application 2011/0318905 to Chiruvolu et al., entitled “Silicon/Germanium Nanoparticle Inks, Laser Pyrolysis Reactors for the Synthesis of Nanoparticles and Associated Methods,” incorporated herein by reference. The silicon particles had an average primary particle diameter of about 7 nm. Two dispersions (Samples 11 and 12) were a 5 weight percent dispersion of n++doped silicon nanoparticles in isopropyl alcohol. Two other dispersions (Samples 13 and 14) were formed from a 6.3 weight percent dispersion of phosphorous doped silicon particles in a blend of isopropyl alcohol and ethylene glycol. Samples 13 and 14 were sonicated and centrifuged and subsequently decanted from the solid phase following centrifugation. The composition and corresponding amount of impurities in the slurries and the inks were measured using ICP-MS. The results of the ICP-MS analysis are displayed in Table 4.

TABLE 4

| | Concentration of Metal | | Concentration of Metal | |
|---|---|---|---|---|
| | Contaminants | | Contaminants | |
| | (ppb by wt) | | (ppb by wt) | |
| | Sample 11 | Sample 12 | Sample 13 | Sample 14 |
| Aluminum | 25 | 2.6 | <0.5 | 0.59 |
| Chromium | 10 | 9.1 | <0.5 | 0.62 |
| Copper | 2.7 | 2.7 | <0.5 | 0.55 |
| Iron | 62 | 39 | 1.4 | 2.3 |
| Lead | <0.5 | <0.5 | <0.5 | <0.5 |
| Manganese | 1.7 | 2.1 | <0.5 | <0.5 |
| Molybdenum | 1 | 0.87 | <0.5 | <0.5 |
| Nickel | 7.8 | 5.7 | <0.5 | <0.5 |
| Titanium | 3.8 | 2.6 | 0.84 | <0.5 |
| Zinc | 9.5 | 4.4 | 3 | 2.3 |
| Calcium | 74 | 10 | 3.2 | 6.3 |
| Magnesium | 11 | 5 | <0.5 | 12 |
| Potassium | 23 | 7.3 | 2.4 | 1.9 |
| Sodium | 19 | 4.8 | 1.4 | 1.3 |

As seen from Table 4, the relative amount of metallic impurities is generally less in the centrifuged dispersions than it is in the dispersions that were not centrifuged for purification. Thus, the centrifugation process is correspondingly seen to be effective at removing impurities with metal elements, and the differences were not believed to be associated with the differences in solvents or concentrations.

### Example 3

### Impurities in Screen Printing Pastes

This Example demonstrates impurities in screen printing pastes formed with a purified EC. The purity was assessed by the concentrations of metal contaminants in the pastes.

To demonstrate purity, paste samples were prepared from concentrated dispersions of silicon nanoparticles that were formed as described in Example 2. For this Example, the paste samples were prepared from n++, doped crystalline silicon particles having an average primary particle size of 20 nm. For each paste sample, a slurry was formed by adding an appropriate amount of nanoparticle powder to a volume of isopropyl alcohol (“IPA”). The mixture was then initially mixed by bath sonication for 3 hr. at ambient temperature to form a dispersion. The dispersion was then centrifuged at 9500 rpm for 20 minutes to remove more poorly dispersed components of the dispersion. The supernatant was then decanted to another centrifuge tube and centrifuged at 9500 rpm for another 20 min. The supernatant of the second centrifugation was then decanted and placed in a rotovap for 30 min. at 137 mbar, to partially remove IPA and concentrate the dispersion to some extent. Subsequently, a volume of propylene glycol (“PG”) was added to the concentrated dispersion and the resulting mixture was subjected to post-centrifugation sonication for 3 hr. at ambient temperature. The sonicated mixture was then placed in the rotavap again to further remove IPA until no further IPA was removed. After this step, the rotavapored mixture was then transferred to a sample container.

With respect to the addition of the EC, the formation included the step of forming a filtration purified EC/Terpineol solution as described in Example 1 above and a step for mixing the EC/Terpineol solution with a base paste by THINKY mixer to form final paste. The final paste samples comprised 10 wt %-14 wt % silicon particles, majority of PG, and some residue of IPA.

Five samples, samples 15-19, were prepared as described above. Metal concentrations in the samples were measured by ICP-MS and the results are reported in ppb by weight in Table 5, below. Referring to the table, all paste samples comprising purified EC demonstrated significant reduction in transition metal and non-transition metal concentrations relative to the ink sample prepared from as-received EC. Additionally, the data presented in Table 5 demonstrates that, for the paste samples tested, filtration generally proved more effective at reducing most transition metal concentrations in the pastes relative to acid wash purification, although acid wash was particularly effective at iron removal. In particular, samples 16 and 17 (filtration purification) had a total transition metal concentrations of 192.21 and 73.1 ppb, respectively, while sample 18 (acid wash purification) had a slightly larger total transition metal concentration of 229.5 ppb. Table 5 also demonstrates the total transition metal concentration in the paste sample comprising EC purified with more than 3 filters (sample 17) was less than 50% of the total transition metal concentration in the past sample comprising EC purified with 3 filters (sample 15). These results are consistent with EC purification results demonstrated in Example 1.

With respect to non-transition metals, for the paste sample tested, the data presented in Table 5 demonstrates that filtration can better reduce metal concentrations in some aspects and acid wash filtration can better reduce metal concentrations in other aspect. Referring to Table, 5, the paste samples 16 and 17 (filtration purified EC) had significantly lower aluminum and boron concentrations relative to the paste sample 18 (acid washed purified EC). On the other hand, sample 18 had reduced calcium and magnesium concentrations relative to samples 16 and 17. Table 5 also demonstrates that sample 19, comprising acid washed and filtration purified EC, in general, had lower transition metal and non-transition metal concentrations relative to all other samples. These results suggest that EC purification comprising acid wash purification and filtration purification can synergistically improve paste purity.

TABLE 5

| | | | Sample 17 | | Sample 19 |
|---|---|---|---|---|---|
| | Sample 15 | Sample 16 | Filtration | Sample 18 | Acid washed + |
| | Un-purified | Filtration EC | (more filters) | Acid washed | filtration |
| | EC Paste | Paste | EC Paste | EC Paste | EC Paste |
| Chromium | 16 | 4 | 5.2 | 9.2 | 3.3 |
| Copper | 42 | 2.6 | 1.4 | 5.3 | <0.5 |
| Iron | 380 | 73 | 23 | 19 | 6.7 |
| Lead | <0.5 | 0.5 | <0.5 | <0.5 | <0.5 |
| Molybdenum | 1.1 | <0.5 | <0.5 | <0.5 | <0.5 |
| Nickel | 1100 | 81 | 29 | 130 | 1.4 |
| Titanium | 13 | 11 | 2.5 | 11 | 1.4 |
| Zinc | 100 | 20 | 12 | 55 | 31 |
| Total | 1652.1 | 192.1 | 73.1 | 229.5 | 43.8 |
| Transition | | | | | |
| Metal | | | | | |
| Concentration | | | | | |
| Aluminum | 9.6 | 15 | 14 | 36 | 11 |
| Boron | 9.6 | 4.2 | 4.7 | 19 | 3.0 |
| Calcium | 1900 | 290 | 280 | 110 | 40 |
| Magnesium | 350 | 61 | 54 | 24 | 16 |
| Potassium | 270 | 67 | 44 | 66 | 40 |
| Sodium | 55,000 | 38 | 24 | 39 | 29 |

### Example 4

### Viscosity of Screen-Printing Pastes Formed with Purified EC

This Example demonstrates the viscosity of screen printing pastes formed with ethyl cellulose following purification.

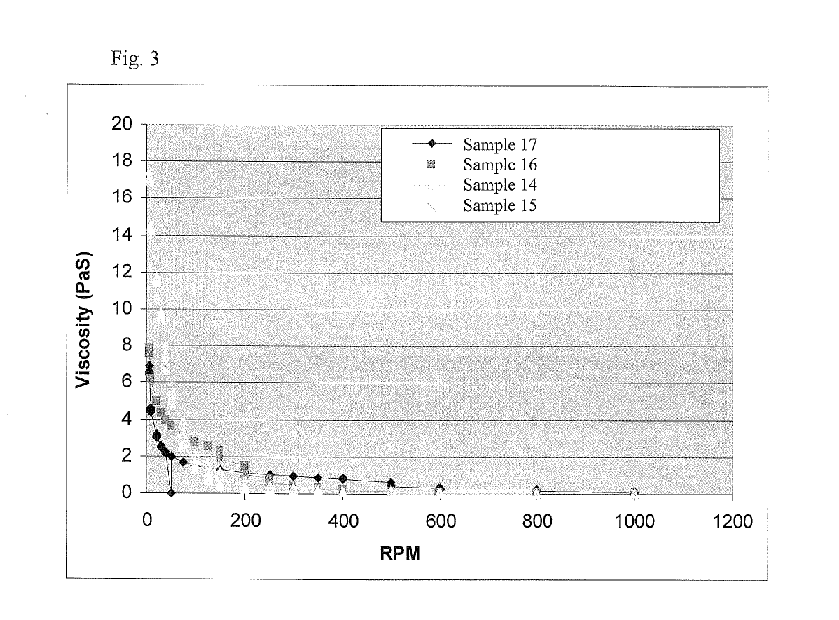

To demonstrate viscosity, 3 screen printing pastes, Samples 20-23 were prepared as described above in Example 2. Sample 20 was prepared using commercial EC without purification, and samples 21 and 22 were prepared using EC purified. The viscosity of each sample was then measured over a range of shear rates using a rheometer. The viscosity of sample 19 of Example 3 was also measured in the same way. Results of the viscosity measurements are displayed in Table 6 and FIG. 3. Table 6 and FIG. 3 reveal that, relative to the samples having a higher EC concentration, the viscosity of the of paste samples having lower EC concentrations generally have a lower viscosity at lower shear rate and a higher viscosity at higher sheer rate. Notably, sample 19 from Example 3 had the highest viscosity at the lowest shear rate and lowest viscosity at the highest sheer rate.

TABLE 6

| Sample ID | Spindle | 5 rpm | 50 rpm | 350 rpm | 1000 rpm |
|---|---|---|---|---|---|
| 20 (w/o purification) | 50-2 | 12.1 | 5.9 | 0.128 | 0.044 |
| 21 (Purified) | 50-2 | 17.0 | 5.3 | 0.109 | 0.035 |
| 22 (Purified) | 50-2 | 7.6 | 3.6 | 0.257 | 0.044 |
| 23 (Purified) | 50-2 | 6.5 | 2.0 | 0.885 | 0.095 |

### Example 5

### Viscosity and Performance of Screen-Printing Pastes Formed with EC without Extra Purification

This example demonstrates the effects of ethyl cellulose (“EC”) on the performance of screen printing pastes. The inks in this example were formed with commercial EC without purification.

For this Example, 7 paste samples were prepared as shown in Table 7. The samples were prepared similarly as described in Example 3. Sample 23 was PG based without EC. Samples 24-29 comprised unpurified EC at a concentration denoted in Table 7. The samples were prepared with 20 nm, n++, doped crystalline silicon nanoparticles. Except for sample 23 which had silicon nanoparticle concentration “[SiNP]” of 10-14 wt %, the samples 24 to 29 had [SiNP] and EC concentration “[EC]” vary from 3-6 wt % and 0-6.7 wt %, respectively.

TABLE 7

| | Sample No. | | | | | | |
|---|---|---|---|---|---|---|---|
| | 23 | 24 | 25 | 26 | 27 | 28 | 29 |
| EC | 0 | 4.7 | 6.7 | 0.85 | 2.5 | 0.65 | 3.3 |
| (wt %) | | | | | | | |

The paste samples were used to manually screen print lines and dots on a silicon wafer substrate. Specifically, a manual screen printer and/or an HMI semi automatic screen printer were used for the screen printing trials. Trampoline mounted screens from Sefar Inc. with long elongation polyester mesh were used. The typical mesh count was 380 threads per inch with mesh opening 36 μm, thread diameter 27 μm, open area 42% and mesh thickness 55 μm. 5 μm thick MM-B emulsion from Sefar Inc. that is capable of ultra-fine resolution and crisp edge definition was used. This emulsion has good resolution potential and a superior resistance to chemical solvents and abrasive pastes. To screen print, a screen was first prepared by depositing an appropriate volume of paste onto one end of a screen. For each screen print cycle, the screen was then suspended a short distance above a new wafer substrate and the screen was flooded by placing ink on the screen. After flooding, the paste was printed by pulling a squeegee across the screen. Between each print cycle, the paste allowed to rest on the screen for about 1 min for continuous manual printing mode. The screens were masked to have dot and/or line patterns. After printing, the printed features were cured by heating the printed wafer substrates at a low temperature of 200° C. for 5 min. in Air on a hotplate. To further remove polymer additives, escalated temperatures were necessary. Unless specified, images of printed films were taken from the samples treated with the low temperature.

### Printing Characteristics—Effect of Polymer Additive

In this study, samples 23 and 26 from Table 7 were characterized to demonstrate the improvement of printability of paste and quality of printed features due to the additive.

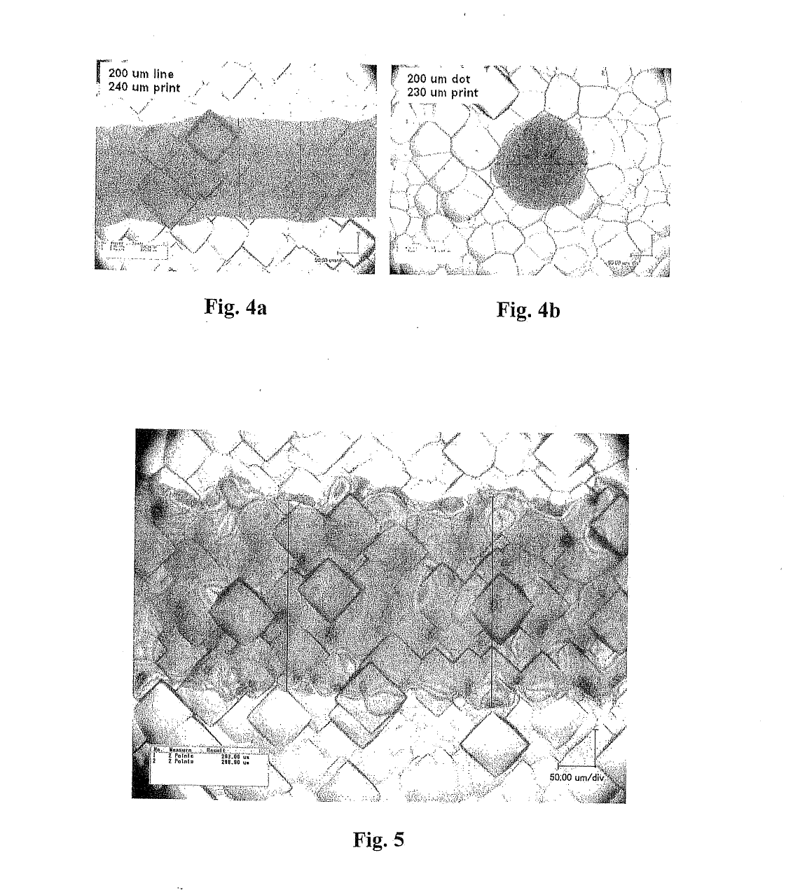

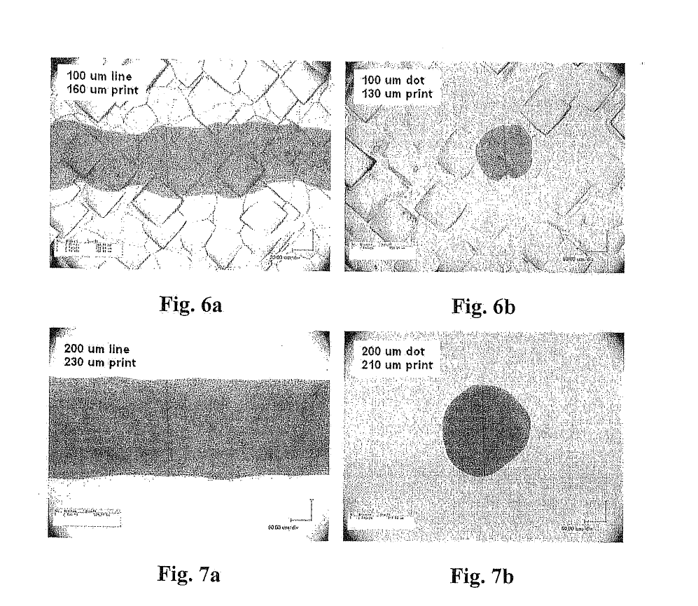

The sample prepared with polymer additive had improved edge definition relative to the sample prepared without polymer additive. FIG. 4 series are optical microscopy images showing a line (4a) and a dot (4b) printed on a silicon wafer during the 10^{th} print cycle with paste sample 26. The line and dot were printed with a width/diameter of about 200 Comparison of FIG. 4a (sample 26) and FIG. 5 (a sample without EC representative of sample 23) shows the sample with EC additive has improved printing quality with better edge definition, less spreading, and more uniformity. However, FIGS. 4a and 4b reveal some level of spreading after printing was still present. In particular, the line width and dot diameter spread by up to 20% and 15%, respectively. The existence of some spreading is likely due to low viscosity at high shear rate or insufficiency of EC content. Furthermore, it is noticed that smaller printed patterns and rougher substrate surface are generally easier to cause a relatively larger degree of post-print spreading. FIG. 6 series are analogous to FIG. 4 series but show a line (6a) and a dot (6b) printed with a width/diameter of 100 μm. These figures reveal that for these smaller patterns, the line width and dot diameter spread by up to 60% and 30%, respective, suggesting a relatively larger degree of post-print spreading with smaller printed structures. FIG. 7 series are analogous to FIG. 4 series showing lines (7a) and dots (7b) printed on polished silicon wafer during the 10^{th} print cycle. Comparison of these figures, demonstrates that screen printing on a polished wafer substrate slightly reduced the degree of post-print spreading with 15% (line) and 5% (dot) spreading. In general, it was observed that the spreading is usually more evident in larger facet areas on textured wafers. Above analysis suggests that adjusting paste rheology and chemistry by increase of EC/terpineol solution in Si paste can further improve quality of printed features.

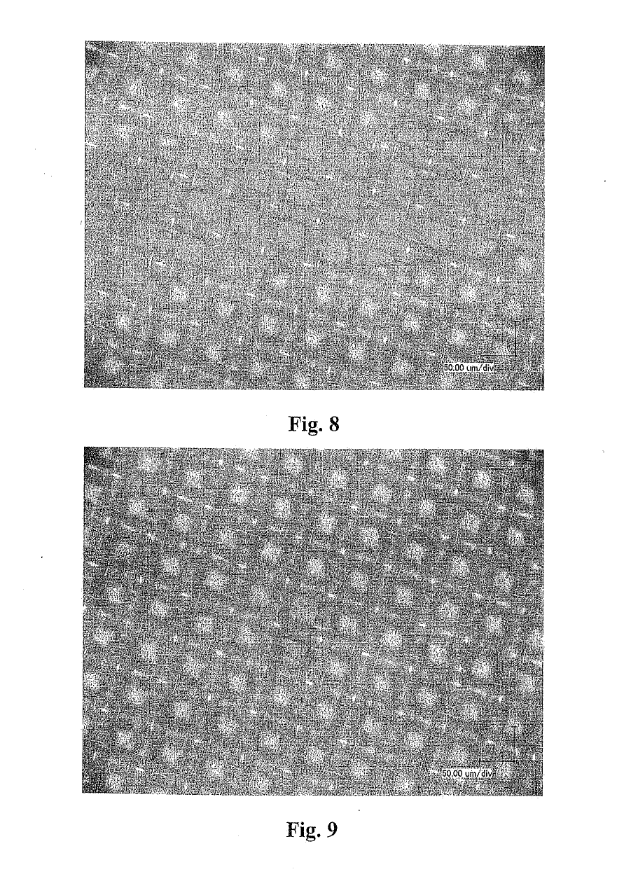

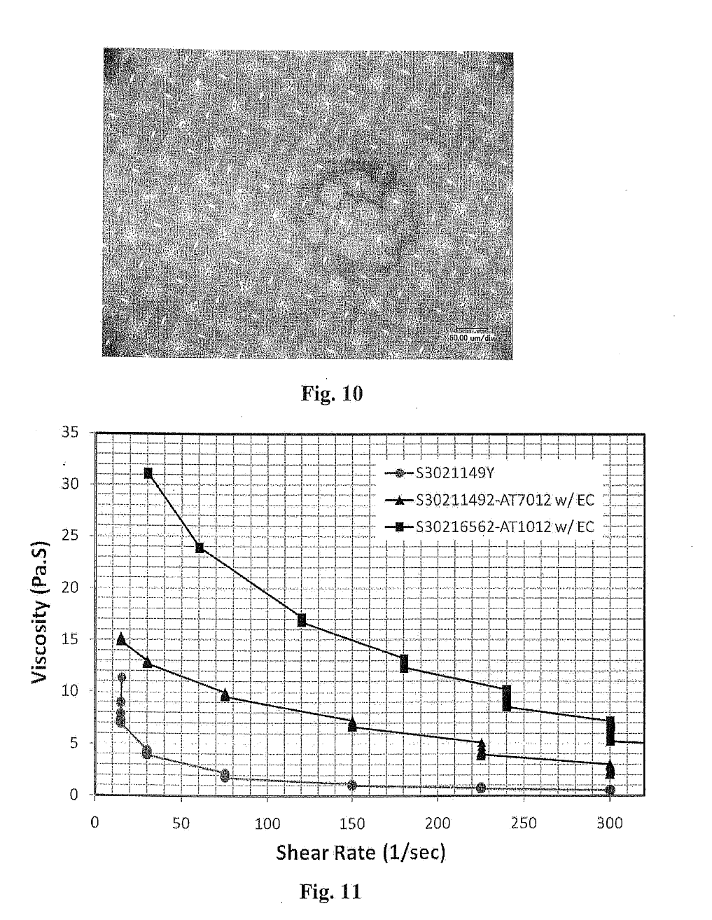

The sample prepared with a polymer additive had significantly reduced screen clogging relative to the sample prepared without polymer additive. FIGS. 8 and 9 are optical microscopy images of the screens used to print, respectively, a 200 μm line and 100 μm dot with paste sample 4, obtained after 2 hours of continuous printing. FIG. 10 is an analogous optical microscopy image of a screen used to print a dot with paste sample 23. The figures reveal that the screen used print sample 23 had noticeable clogging around the edges of the screen pores and, in the case of dot prints, almost total occlusion of some of the pores. Furthermore, the figures demonstrate the screens used to print paste sample 26 (prepared with additive of EC polymer in terpineol) had only minimal clogging near the edges of the pores and significantly reduced clogging relative to the screens used print paste sample 23. In addition, FIG. 9 from the above comparison is a 100 μm dot, which only had very minor clogging, suggesting the larger dots such as 200 μm should be no clogging as well because smaller screen openings more easily get clogged than the larger ones. It is further noted that the reduction of clogging is not necessarily only related to polymer additive (e.g. EC), but also related to solvent system (e.g. terpineol) and entire paste system.

### Paste Rheology

To demonstrate the rheology of screen printing pastes, 3 paste samples (samples 23-25) were used from Table 7. A rheometer (RS/-CPS, Brookfiled) was used to apply different shear rates to the paste samples and the corresponding viscosities were measured. FIG. 11 is a graph containing plots of shear rate versus viscosity for the different samples at different shear rates. The figure demonstrates that paste samples formed with EC (samples 24 and 25) had greater viscosities over the range of tested shear rates and, therefore, is consistent with above printing data, suggesting that EC can be a particularly beneficial component of inks formed for use in screen printing. The figure also demonstrates that sample 25 had a larger viscosity than sample 24 over the tested range of shear rates and demonstrates increase of EC concentration can further increases Si paste viscosity.

### Printing Characteristics—Concentration EC and Nanoparticle Concentrations

To demonstrate the effect of different concentrations of the ink components, specifically, concentration of ethyl cellulose [EC] and ratio of Si nanoparticles to EC concentration “[SiNP]/[EC]”, samples 26-29 from Table 7 were chosen for analysis.

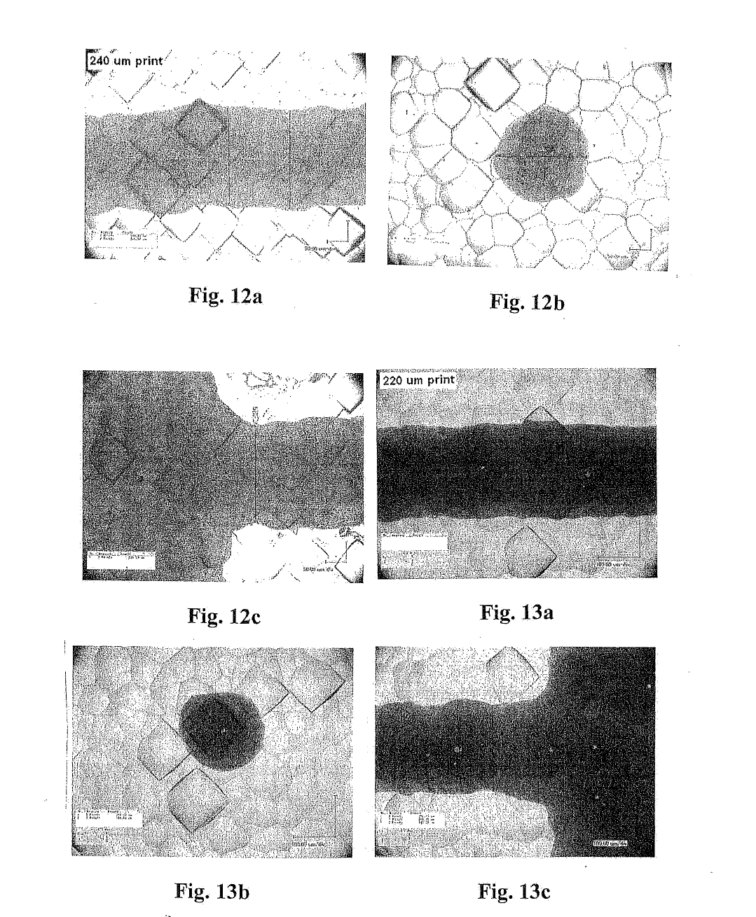

The effect of EC concentration is demonstrated in FIGS. 12 & 13 series. The ink samples were used to print lines and dots with corresponding widths and diameters of 200 μm on silicon wafer substrates, as described above. FIGS. 12a and 13a are optical microscopy images showing top-views of lines printed during the 10^{th} print cycle with ink samples 26 and 27, respectively. The figure demonstrates that increased EC concentrations can reduce post-print spreading and improve feature definition. In particular, these figures reveal that the line printed with sample 26 (0.85 wt % EC) spread to about 240 μm while the line printed with sample 27 (2.5 wt % EC) spread to only about 220 μm after printing. FIGS. 12b, 13b) and (12c, 13c) are analogous to FIGS. 12a, 13a) and show dots (FIGS. 12b and 13b) and irregular patterns (FIGS. 12c and 13c) printed with ink samples 26 (FIG. 12 series) and 27 (FIG. 13 series). These figures similarly show less post-print spreading of features printed with ink sample 27, relative to ink sample 26.

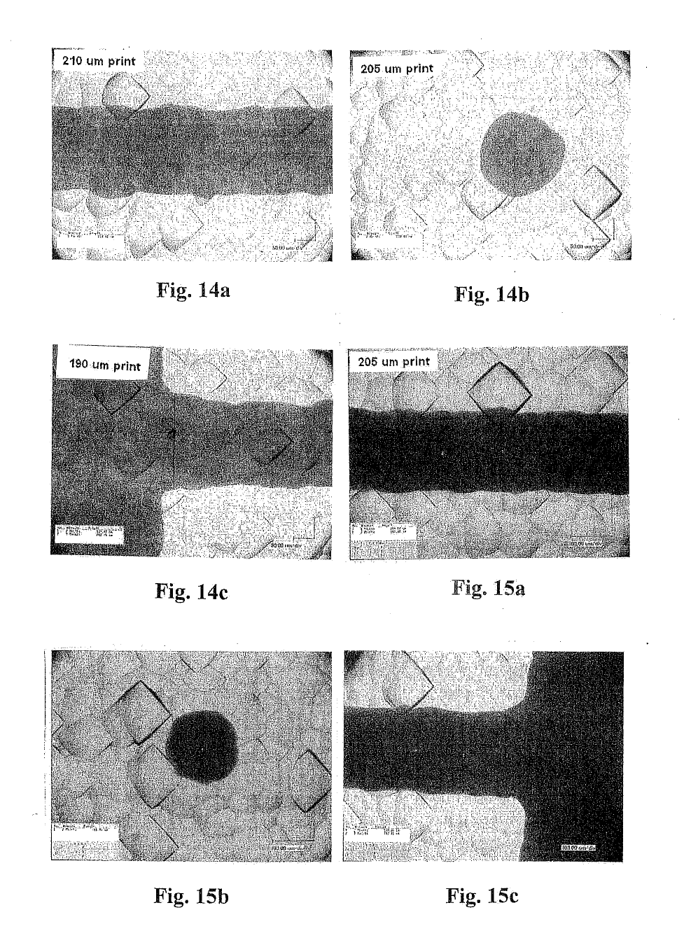

The effect of different [SiNP]/[EC] values at lower EC concentration is demonstrated in FIGS. 14a-14c. With respect to samples 26-29, [SiNP]/[EC] varied from lowest to highest as: sample 29<sample 27<sample 26<sample 28. FIG. 14a is an optical microscopy image showing top-view of line printed during the 10^{th} print cycle with ink sample 28. Comparison of FIG. 14a (sample 28) with FIG. 12a (sample 26) demonstrates that at lower EC concentrations, less post-print spreading was achieved by increasing [SiNP]/[EC]. In particular, the figures demonstrates that lines printed with sample 26 spread to about 240 μm while the line printed with sample 28 spread to only about 210 μm. FIGS. 14b and 14c are analogous to FIG. 14a and show a dot (FIG. 14b) and an irregular pattern (FIG. 14c) printed with ink sample 28. Comparison of these figures with FIGS. 12b and 12c similarly show less post-print spreading of features printed with ink sample 28, relative to ink sample 26. It is noted that the increase of [SiNP]/[EC] was mainly done by increase of Si loading. To what extent Si loading can be increased at such low range of [EC] without compromising the printability and printing quality can be further studied.

The effects of different [SiNP]/[EC] values at higher EC concentration is demonstrated in FIGS. 15a-15c. FIG. 15a is an optical microscopy image showing a top-view of a line printed during the 10^{th} print cycle with ink sample 29. Comparison of this figure to FIG. 13a (sample 27) demonstrates that at higher EC concentrations, less post-print spreading was achieved by decreasing [SiNP]/[EC], in contrast to what was observed at lower EC concentrations. In particular, the figures demonstrate that lines printed with sample 29 spread to only 205 μm while the line printed with sample 27 spread to about 220 μm. FIGS. 15b and 15c are analogous to FIG. 15a and show a dot (FIG. 15b) and an irregular pattern (FIG. 15c) printed with ink sample 29. These figures similarly show less post-print spreading of features printed with ink sample 29, relative to ink sample 27. Furthermore, it is noted that the decrease of [SiNP]/[EC] was achieved mainly by increase of EC content. To what extent EC can be increased until the printability and printing quality reach saturation platform is worth of continuous investigation.

The specific embodiments above are intended to be illustrative and not limiting. Additional embodiments are within the broad concepts described herein. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A nanoparticle ink comprising at least about 0.1 weight percent silicon/germanium-based inorganic nanoparticles and at least about 1 weight percent polymer having a molecular weight of at least 500 daltons, wherein the paste has an iron content of no more than about 100 ppb and wherein the polymer comprises an organic polymer comprising a cellulose-based polymer, a poly(vinyl alcohol), a poly(vinyl ester), polyvinyl amides, a polysiloxane polymer, polyacrylates, polyacrylic acid, polyvinyl butyrl or a combination thereof.

2. The nanoparticle ink of claim 1 wherein the silicon/germanium-based inorganic nanoparticles comprise elemental silicon, elemental germanium, mixtures thereof or alloys thereof.

3. The nanoparticle ink of claim 1 wherein the inorganic nanoparticles comprise a dopant.

4. The nanoparticle ink of claim 1 wherein the ink is a paste exhibiting non-newtonian rheology.

5. The nanoparticle ink of claim 1 wherein the silicon/germanium-based nanoparticles comprise silicon oxide, silicon nitride, silicon oxynitride or combinations thereof.

6. The nanoparticle ink of claim 1 wherein the inorganic nanoparticles comprise elemental silicon, the organic polymer comprises a cellulose-based polymer and the nanoparticle paste further comprises an alcohol solvent.

7. The nanoparticle ink of claim 1 wherein the nanoparticle paste comprises from about 0.5 to about 15 weight percent inorganic nanoparticles and at least 2 weight percent polymer, and wherein the polymer comprises ethyl cellulose.

8. The nanoparticle ink of claim 1 having an iron content of no more than about 60 ppb.

9. The nanoparticle ink of claim 1 having a chromium contamination, copper contamination and nickel contaminations individually of no more than about 100 ppb.

10. A method for forming a component of a device on a structure, the method comprising:
printing a pattern of the ink of claim 1 onto a substrate; and
processing the printed ink with heat such that the component is formed.

11. The method of claim 10 wherein the substrate comprises a silicon wafer.

12. A cellulose polymer having a iron contamination, chromium contamination, copper contamination and nickel contamination individually of no more than about 100 ppb by weight as evaluated in a 7 weight percent solution.

13. The cellulose polymer of claim 12 wherein the polysaccharide comprises a cellulose ether.

14. The cellulose polymer of claim 12 wherein the cellulose polymer comprises ethyl cellulose.

15. The cellulose polymer of claim 12 having metal contamination for any individual metal of no more than about 400 ppb as evaluated in a 7 weight percent polymer solution.

16. The cellulose polymer of claim 12 having iron contamination, chromium contamination, copper contamination or nickel contamination individually of no more than about 50 ppb as evaluated in a 7 weight percent polymer solution.

17. The cellulose polymer of claim 12 having metal contamination levels of no more than about 100 ppb for any metal as evaluated in a 7 weight percent polymer solution.

18. A method for the purification of an organic polymer soluble at a concentration of at least about 0.5 weight percent in ethanol and having a molecular weight of at least 200 amu, the method comprising:
separating the polymer from an acidified aqueous solution having a pH of no more than about 4 pH units to obtain a polymer with a reduced metal content.

19. The method of claim 18 wherein the acidified aqueous solution comprises solubilzed HCl.

20. The method of claim 18 wherein the acidified aqueous solution comprises a solubilized carboxylic acid.

21. The method of claim 18 wherein the separating is performed with centrifugation.

22. The method of claim 18 further comprising:
adding solvent to the separated polymer to form a re-suspended polymer and performing an additional separation on the re-suspended polymer to form a further purified polymer.

23. The method of claim 18 further comprising mixing the acidified polymer solution for at least about 10 minutes prior to performing the separation.

24. The method of claim 18 further comprising performing initial processing of the polymer prior to forming the acidified solution, the initial processing comprising:
forming a suspension of the polymer in a solvent;
separating the polymer to form an initially purified polymer; and
suspending the initially purified polymer in an acidic solution to form the acidified solution.

25. The method of claim 18 wherein the polymer comprises an ether cellulose and the acidified solution comprises water.

26. A method for the purification of a polymer soluble at a concentration of at least about 0.5 weight percent in ethanol, the method comprising,
filtering a dissolved solution of the polymer through an ion removal media to reduce the iron contamination to no more than about 100 ppb as determined in a 7 weight percent polymer solution.

27. The method of claim 26 wherein the polymer solution comprises an alcohol.

28. The method of claim 26 wherein the filtration is repeated to further reduce transition metal contamination of the polymer.

29. The method of claim 28 wherein the purified polymer has an iron contamination, chromium contamination, copper contamination and nickel contamination individually of no more than about 40 ppb, as evaluated in a 7 weight percent solution of polymer.

30. The method of claim 26 wherein polymer solution during purification has a concentration from about 0.01 weight percent polymer to about 15 weight percent.
